(19) United States
(12) Patent Application Publication
(10) Pub. No.: US 2019/0146340 A1
(43) Pub. Date: May 16, 2019

(54) RADIATION-SENSITIVE RESIN COMPOSITION AND RESIST PATTERN-FORMING METHOD

(71) Applicant: JSR CORPORATION, Tokyo (JP)

(72) Inventors: Motohiro SHIRATANI, Tokyo (JP); Hiromu MIYATA, Tokyo (JP); Takehiko NARUOKA, Tokyo (JP)

(73) Assignee: JSR CORPORATION, Tokyo (JP)

(21) Appl. No.: 16/244,151

(22) Filed: Jan. 10, 2019

Related U.S. Application Data
(63) Continuation of application No. PCT/JP2017/025189, filed on Jul. 10, 2017.

(30) Foreign Application Priority Data
Jul. 12, 2016 (JP) 2016-137489

(51) Int. Cl. G03F 7/038; G03F 7/039; G03F 7/16; G03F 7/20; G03F 7/32; C08F 220/28; G03F 7/38

(52) U.S. Cl. CPC G03F 7/038; G03F 7/039; G03F 7/162; G03F 7/2037; C08F 2220/281; G03F 7/168; C08F 220/28; G03F 7/38; G03F 7/322

(57) ABSTRACT

A radiation-sensitive resin composition includes a polymer; a radiation-sensitive acid generator; and a solvent. The polymer includes a first structural unit and a second structural unit. The first structural unit includes: a first acid-labile group represented by formula (A); and an oxoacid group protected by the first acid-labile group, or a phenolic hydroxyl group protected by the first acid-labile group. The second structural unit includes: a second acid-labile group other than the first acid-labile group; and an oxoacid group protected by the second acid-labile group, or a phenolic hydroxyl group protected by the second acid-labile group.

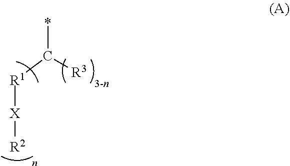

### CROSS-REFERENCE TO RELATED APPLICATIONS

The present application is a continuation application of International Application No. PCT/JP2017/025189, filed Jul. 10, 2017, which claims priority to Japanese Patent Application No. 2016-137489, filed Jul. 12, 2016. The contents of these applications are incorporated herein by reference in their entirety.

### BACKGROUND OF THE INVENTION

### Field of the Invention

The present invention relates to a radiation-sensitive resin composition and a resist pattern-forming method.

### Discussion of the Background

For forming various types of electronic device structures for a semiconductor device, a liquid crystal device and the like, resist pattern-forming methods by way of photolithography are employed. In the resist pattern-forming methods, for example, a radiation-sensitive resin composition, etc., for forming a resist pattern on a substrate is used. According to the radiation-sensitive resin composition, an acid is generated in light-exposed regions upon irradiation with a radioactive ray, e.g., a far ultraviolet ray such as an ArF excimer laser, an electron beam, etc., and a catalytic action of the acid produces a difference in rate of dissolution in a developer solution between the light-exposed regions and light-unexposed regions, thereby enabling the resist pattern to be formed on the substrate.

Such a radiation-sensitive resin composition is required to enable a resist pattern to be formed which is superior in lithography performances such as LWR (Line Width Roughness) performance and CDU (Critical Dimension Uniformity) performance, and is highly accurate. To address the demand, the structure of the polymer contained in the radiation-sensitive resin composition has been extensively studied, and it is known that incorporation of a lactone structure such as a butyrolactone structure and a norbornanelactone structure can enhance the adhesiveness of the resist pattern to a substrate, and improve the aforementioned performances (see Japanese Unexamined Patent Application, Publication Nos. H11-212265, 2003-5375 and 2008-83370).

### SUMMARY OF THE INVENTION

According to an aspect of the present invention, a radiation-sensitive resin composition includes a polymer; a radiation-sensitive acid generator; and a solvent. The polymer includes a first structural unit and a second structural unit. The first structural unit includes: a first acid-labile group represented by formula (A); and an oxoacid group protected by the first acid-labile group, or a phenolic hydroxyl group protected by the first acid-labile group. The second structural unit includes: a second acid-labile group other than the first acid-labile group; and an oxoacid group protected by the second acid-labile group, or a phenolic hydroxyl group protected by the second acid-labile group.

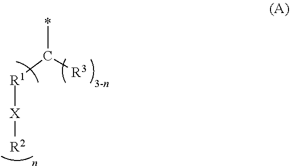

In the formula (A), R¹ represents a single bond or a divalent hydrocarbon group having 1 to 20 carbon atoms that is unsubstituted or substituted with a hydroxy group, an amino group, a cyano group, a nitro group or a fluorine atom; X represents a carbonyl group, a sulfonyl group, a sulfonyloxy group, —O—, or —S—; R² and R³ each independently represent a monovalent hydrocarbon group having 1 to 20 carbon atoms that is unsubstituted or substituted with a hydroxy group, an amino group, a cyano group, a nitro group or a fluorine atom; n is an integer of 1 to 3; and * denotes a bonding site to an oxy group in the oxoacid group protected or the phenolic hydroxyl group protected, wherein in a case in which R¹, R² and R³ are each present in a plurality of number, R¹s are identical or different, R²s are identical or different, and R³s are identical or different. Or at least two of: one or a plurality of R¹s; one or a plurality of R²s; and one or a plurality of R³s taken together represent an alicyclic structure having 3 to 20 ring atoms together with the carbon atom or carbon chain to which the at least two of the one or the plurality of R¹s, the one or the plurality of R²s and the one or the plurality of R³s bond, and R¹ other than the at least two of the one or the plurality of R¹s represents a single bond or a divalent hydrocarbon group having 1 to 20 carbon atoms that is unsubstituted or substituted with a hydroxy group, an amino group, a cyano group, a nitro group or a fluorine atom; X represents a carbonyl group, a sulfonyl group, a sulfonyloxy group, —O—, or —S—; and R² other than the one or the plurality of R²s and R³ other than the one or the plurality of R³s each independently represent a monovalent hydrocarbon group having 1 to 20 carbon atoms that is unsubstituted or substituted with a hydroxy group, an amino group, a cyano group, a nitro group or a fluorine atom; n is an integer of 1 to 3.

According to another aspect of the present invention, a resist pattern-forming method includes applying the radiation-sensitive resin composition directly or indirectly on an upper face side of a substrate to form a resist film. The resist film is exposed. The resist film exposed is developed.

### DESCRIPTION OF THE EMBODIMENTS

According to one embodiment of the invention, a radiation-sensitive resin composition contains a polymer (hereinafter, may be also referred to as “(A) polymer” or “polymer (A)”), a radiation-sensitive acid generator (hereinafter, may be also referred to as “(B) acid generator” or “acid generator (B)”), and a solvent (hereinafter, may be also referred to as “(C) solvent” or “solvent (C)”), in which the polymer has a first structural unit (hereinafter, may be also referred to as “structural unit (I)”) that includes: a first acid-labile group represented by the following formula (A) (hereinafter, may be also referred to as “acid-labile group (1)”); and an oxoacid group protected by the first acid-labile group, or a phenolic hydroxyl group protected by the first acid-labile group, and a second structural unit (hereinafter, may be also referred to as “structural unit (II)”) that includes: a second acid-labile group other than the first acid-labile group (hereinafter, may be also referred to as “acid-labile group (2)”); and an oxoacid group protected by the second acid-labile group, or a phenolic hydroxyl group protected by the second acid-labile group.

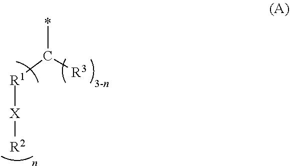

wherein, in the formula (A), R¹ represents a single bond or a divalent hydrocarbon group having 1 to 20 carbon atoms that is unsubstituted or substituted with a hydroxy group, an amino group, a cyano group, a nitro group or a fluorine atom; X represents a carbonyl group, a sulfonyl group, a sulfonyloxy group, —O—, or —S—; R² and R³ each independently represent a monovalent hydrocarbon group having 1 to 20 carbon atoms that is unsubstituted or substituted with a hydroxy group, an amino group, a cyano group, a nitro group or a fluorine atom; n is an integer of 1 to 3; and * denotes a bonding site to an oxy group in the oxoacid group protected or the phenolic hydroxyl group protected,

wherein in a case in which R¹, R² and R³ are each present in a plurality of number, R¹s are identical or different, R²s are identical or different, and R³s are identical or different, or at least two of: one or a plurality of R¹s; one or a plurality of R²s; and one or a plurality of R³s taken together represent an alicyclic structure having 3 to 20 ring atoms together with the carbon atom or carbon chain to which the at least two of the one or the plurality of R¹s, the one or the plurality of R²s and the one or the plurality of R³s bond, and R¹, R² and R³ other than the at least two of the one or the plurality of R¹s, the one or the plurality of R²s and the one or the plurality of R³s are as defined above.

According to another embodiment of the invention, applying the radiation-sensitive resin composition according to the one embodiment directly or indirectly on an upper face side of a substrate to form a resist film; exposing the resist film; and developing the resist film exposed.

The “hydrocarbon group” as referred to includes chain hydrocarbon groups, alicyclic hydrocarbon groups and aromatic hydrocarbon groups. This “hydrocarbon group” may be a saturated hydrocarbon group or an unsaturated hydrocarbon group. The “chain hydrocarbon group” as referred to means a hydrocarbon group that is constituted with only a chain structure without having a cyclic structure, and the term “chain hydrocarbon group” includes both linear hydrocarbon groups and branched hydrocarbon groups. The “alicyclic hydrocarbon group” as referred to means a hydrocarbon group that has as a ring structure not an aromatic ring structure but only an alicyclic structure, and the term “alicyclic hydrocarbon group” includes both monocyclic alicyclic hydrocarbon groups and polycyclic alicyclic hydrocarbon groups. However, it is not necessary for the alicyclic hydrocarbon group to be constituted with only an alicyclic structure, and a part thereof may have a chain structure. The “aromatic hydrocarbon group” as referred to means a hydrocarbon group that has an aromatic ring structure as a ring structure. However, it is not necessary for the aromatic hydrocarbon group to be constituted with only an aromatic ring structure, and a part thereof may have a chain structure and/or an alicyclic structure. The “number of ring atoms” as referred to herein means the number of atoms constituting a ring of the aromatic ring structure, the aromatic heterocyclic structure, the alicyclic structure or the aliphatic heterocyclic structure, and in the case polycyclic ring structures, the “ring atoms” means the number of atoms constituting the polycycle.

The radiation-sensitive resin composition and the resist pattern-forming method of the embodiments of the present invention enable a resist pattern superior in LWR performance and CDU performance to be formed. Therefore, these can be suitably used in manufacture of semiconductor devices in which further progress of miniaturization is expected in the future.

### Radiation-Sensitive Resin Composition

The radiation-sensitive resin composition of the embodiment of the present invention contains the polymer (A), the acid generator (B) and the solvent (C). The radiation-sensitive resin composition may contain (D) an acid diffusion controller as a favorable component. Furthermore, the radiation-sensitive resin composition may contain other optional component within a range not leading to impairment of the effects of the present invention. Hereinafter, each component will be described.

### (A) Polymer

The polymer (A) has the structural unit (I) that includes: the acid-labile group (1) represented by the following formula (A); and an oxoacid group protected by the acid-labile group (1), or a phenolic hydroxyl group protected by the acid-labile group (1), and the second structural unit that includes: the acid-labile group (2) other than the acid-labile group (1); and an oxoacid group protected by the acid-labile group (2), or a phenolic hydroxyl group protected by the acid-labile group (2). Due to the polymer (A) having the structural unit (I) and the structural unit (II), the radiation-sensitive resin composition of the embodiment of the present invention is capable of leading to superior LWR performance and CDU performance. Although not necessarily clarified and without wishing to be bound by any theory, the reason for achieving the effects described above due to the radiation-sensitive composition having the aforementioned constitution is inferred as in the following, for example. Specifically, the acid-labile group (1) included in the structural unit (I) has comparatively high polarity due to including a carbonyl group, a sulfonyl group, a sulfonyloxy group, —O—, or —S— having comparatively high polarity at a site represented by X as shown by the following formula (A). Therefore, the structural unit (I) attains a comparatively small rate of change in polarity after dissociation of the acid-labile group (1) through an action of an acid generated from the acid generator (B). Meanwhile, since the structural unit (II) includes the acid-labile group (2) in place of the acid-labile group (1), a comparatively large rate of change in polarity after dissociation of the acid-labile group is attained. As a result, the radiation-sensitive resin composition enables dissolution contrast between the light-exposed regions and the light-unexposed regions to be adjusted appropriately in the resist film to be formed by adjusting the proportions of the structural unit (I) and the structural unit (II) contained in the polymer (A). Accordingly, the radiation-sensitive resin composition is considered to be capable of leading to superior LWR performance and CDU performance.

The polymer (A) may have not only the structural unit (I) and the structural unit (II) but also a structural unit (III) that includes a lactone structure, a cyclic carbonate structure, a sultone structure or a combination thereof, a structural unit (IV) that includes a phenolic hydroxyl group, a structural unit (V) that includes an alcoholic hydroxyl group, etc., as well as other structural unit than the structural units (I) to (V). The polymer (A) may have one, or two or more types of each of the structural units. Each structural unit will be described below.

Structural Unit (I)

The structural unit (I) includes the acid-labile group (1) represented by the following formula (A), and the oxoacid group protected by the acid-labile group (1) or phenolic hydroxyl group protected by the acid-labile group (1). The “oxoacid group” as referred to herein means a group having a structure in which an oxygen atom bonds to a hydrogen atom that can be dissociated as a proton. The “acid-labile group” as referred to herein means a group that protects a polar group including an oxy group such as an oxoacid group or a phenolic hydroxyl group, through substitution of the hydrogen atom bonding to the oxy group, and means a group that is dissociated by an action of an acid.

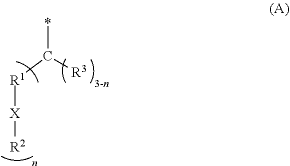

In the above formula (A), R¹ represents a single bond or a divalent hydrocarbon group having 1 to 20 carbon atoms that is unsubstituted or substituted with a hydroxy group, an amino group, a cyano group, a nitro group or a fluorine atom; X represents a carbonyl group, a sulfonyl group, a sulfonyloxy group, —O—, or —S—; R² and R³ each independently represent a monovalent hydrocarbon group having 1 to 20 carbon atoms that is unsubstituted or substituted with a hydroxy group, an amino group, a cyano group, a nitro group or a fluorine atom; n is an integer of 1 to 3; and * denotes a bonding site to an oxy group in the oxoacid group protected or the phenolic hydroxyl group protected,

wherein in a case in which R¹, R² and R³ are each present in a plurality of number, a plurality of R¹s may be identical or different, a plurality of R²s may be identical or different, and a plurality of R³s may be identical or different, and at least two of: one or a plurality of R¹s; one or a plurality of R²s; and one or a plurality of R³s may taken together represent an alicyclic structure having 3 to 20 ring atoms together with the carbon atom or carbon chain to which the at least two of the one or the plurality of R¹s, the one or the plurality of R²s and the one or the plurality of R³s bond.

The oxoacid group protected by the acid-labile group (1) is exemplified by a protected carboxy group, a protected sulfo group, a protected sulfuric acid group, a protected phosphoric acid group, and the like. Of these, the protected carboxy group is preferred.

X represents preferably a carbonyl group.

The divalent hydrocarbon group having 1 to 20 carbon atoms which may be represented by R¹ is exemplified by a divalent chain hydrocarbon group having 1 to 20 carbon atoms, a divalent alicyclic hydrocarbon group having 3 to 20 carbon atoms, a divalent aromatic hydrocarbon group having 6 to 20 carbon atoms, and the like. Specific examples of the divalent hydrocarbon group having 1 to 20 carbon atoms which may be represented by R¹ include groups obtained by each removing one hydrogen atom from monovalent hydrocarbon groups having 1 to 20 carbon atoms exemplified in connection with R² and R³ as described later, and the like.

R¹ represents preferably a single bond, or an alkanediyl group having 1 to 10 carbon atoms that is unsubstituted or substituted with a hydroxy group, an amino group, a cyano group, a nitro group or a fluorine atom.

Examples of the alkanediyl group having 1 to 10 carbon atoms which may be represented by R¹ include a methanediyl group, an ethanediyl group, a propanediyl group, a butanediyl group, a pentanediyl group, a hexanediyl group, and the like. Examples of the substituted alkanediyl group having 1 to 10 carbon atoms which may be represented by R¹ include groups obtained by substituting a part or all of hydrogen atoms included in the alkanediyl group with a hydroxy group, an amino group, a cyano group, a nitro group or a fluorine atom, and the like.

R¹ represents more preferably an alkanediyl group having 1 to 3 carbon atoms, and more preferably a methanediyl group.

The monovalent hydrocarbon group having 1 to 20 carbon atoms which may be represented by R² or R³ is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like. The substituted monovalent hydrocarbon group having 1 to 20 carbon atoms which may be represented by R² or R³ is exemplified by a group obtained by substituting a part or all of hydrogen atoms included in the hydrocarbon group with a hydroxy group, an amino group, a cyano group, a nitro group or a fluorine atom, and the like.

Examples of the monovalent chain hydrocarbon group include:

alkyl groups such as a methyl group, an ethyl group, a n-propyl group, an i-propyl group, a n-butyl group, an i-butyl group, a sec-butyl group and a t-butyl group;

alkenyl groups such as an ethenyl group, a propenyl group and a butenyl group;

alkynyl groups such as an ethynyl group, a propynyl group and a butynyl group; and the like.

Examples of the monovalent alicyclic hydrocarbon group include:

monovalent monocyclic alicyclic saturated hydrocarbon groups such as a cyclopropyl group, a cyclobutyl group, a cyclopentyl group, a cyclohexyl group and a cyclooctyl group;

monovalent monocyclic alicyclic unsaturated hydrocarbon groups such as a cyclobutenyl group, a cyclopentenyl group and a cyclohexenyl group;

monovalent polycyclic alicyclic saturated hydrocarbon groups such as a norbornyl group, an adamantyl group, a tricyclodecyl group and a tetracyclododecyl group;

monovalent polycyclic alicyclic unsaturated hydrocarbon groups such as a norbornenyl group, a tricyclodecenyl group and a tetracyclododecenyl group; and the like.

Examples of the monovalent aromatic hydrocarbon group include:

aryl groups such as a phenyl group, a tolyl group, a xylyl group, a naphthyl group and an anthryl group;

aralkyl groups such as a benzyl group, a phenethyl group, a phenylpropyl group and a naphthylmethyl group; and the like.

Examples of the alicyclic structure having 3 to 20 ring atoms which may be taken together represented by at least two of: one or a plurality of R¹s; one or a plurality of R²s; and one or a plurality of R³s, together with the carbon atom or carbon chain to which the at least two of the one or the plurality of R¹s, the one or the plurality of R²s and the one or the plurality of R³s bond include:

monocyclic alicyclic saturated hydrocarbon structures such as a cyclopropyl structure, a cyclobutyl structure, a cyclopentyl structure, a cyclohexyl structure, a cycloheptyl structure and a cyclooctyl structure;

monocyclic alicyclic unsaturated hydrocarbon structures such as a cyclobutenyl structure, a cyclopentenyl structure and a cyclohexenyl structure;

polycyclic alicyclic saturated hydrocarbon structures such as a norbornyl structure, an adamantyl structure, a tricyclodecyl structure and a tetracyclododecyl structure;

polycyclic alicyclic unsaturated hydrocarbon structures such as a norbornenyl structure, a tricyclodecenyl structure and a tetracyclododecenyl structure; and the like.

R² and R³ each represent preferably a chain hydrocarbon group having 1 to 20 carbon atoms, more preferably an alkyl group having 1 to 5 carbon atoms, and still more preferably a methyl group.

The alicyclic structure having 3 to 20 ring atoms which may be taken together represented by at least two of: one or a plurality of R¹s; one or a plurality of R²s; and one or a plurality of R³s, together with the carbon atom or carbon chain to which the at least two of the one or the plurality of R¹s, the one or the plurality of R²s and the one or the plurality of R³s bond is preferably a monocyclic alicyclic saturated hydrocarbon structure having 3 to 10 ring atoms, or a polycyclic alicyclic saturated hydrocarbon structure having 7 to 15 ring atoms, and more preferably a cyclopentyl structure, a cyclohexyl structure, a cycloheptyl structure, a cyclooctyl structure, an adamantyl structure or a tetracyclododecyl structure. Furthermore, the alicyclic structure is preferably taken together represented by two R³s together with the carbon atom to which the two R³s bond.

In the above formula (A), n is preferably 1 or 2, and more preferably 1.

The acid-labile group (1) represented by the above formula (A) is preferably represented by the following formula (1).

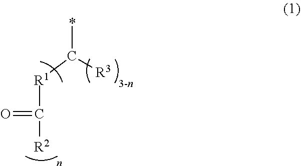

In the above formula (1), R¹, R², R³, n and * are as defined for the above formula (A). R¹ represents preferably a single bond, or an alkanediyl group having 1 to 10 carbon atoms that is unsubstituted or substituted with a hydroxy group, an amino group, a cyano group, a nitro group or a fluorine atom, and the alkanediyl group having 1 to 10 carbon atoms which may be represented by R¹ is similarly exemplified by those in connection with the above formula (A).

Examples of the acid-labile group (1) include groups represented by the following formulae (1-1) to (1-20) (hereinafter, may be also referred to as “groups (1-1) to (1-20)”), and the like.

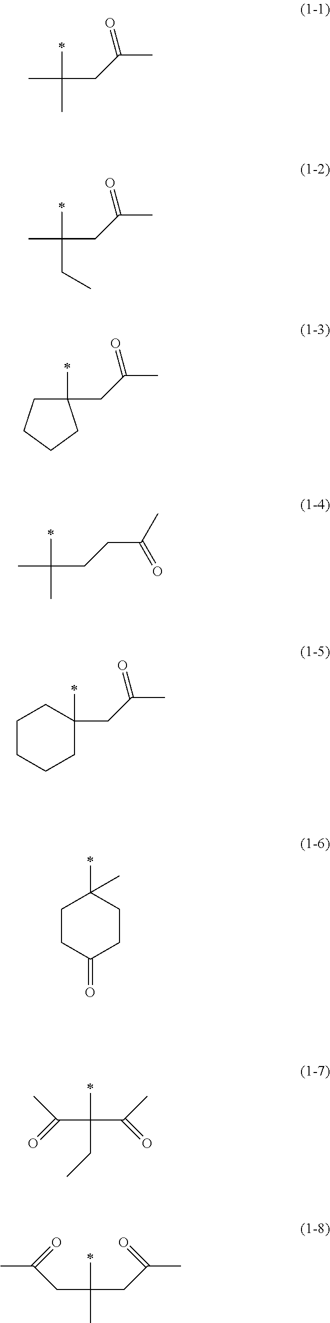

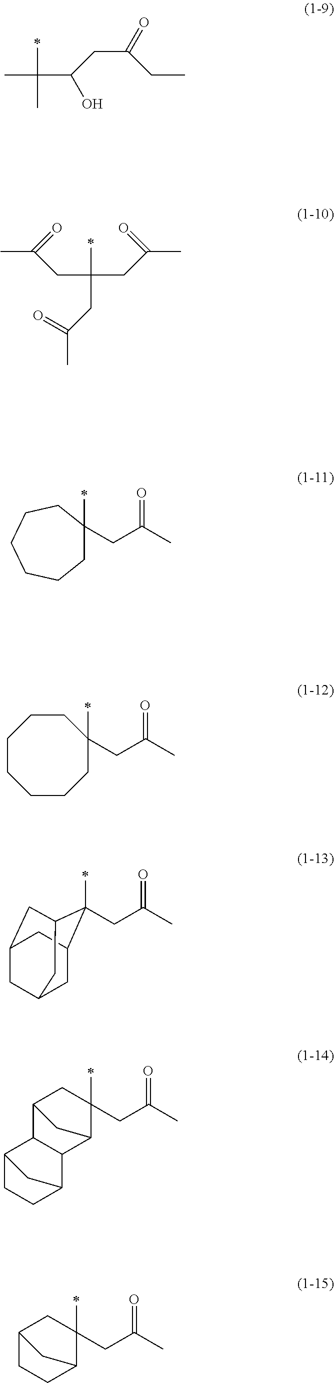

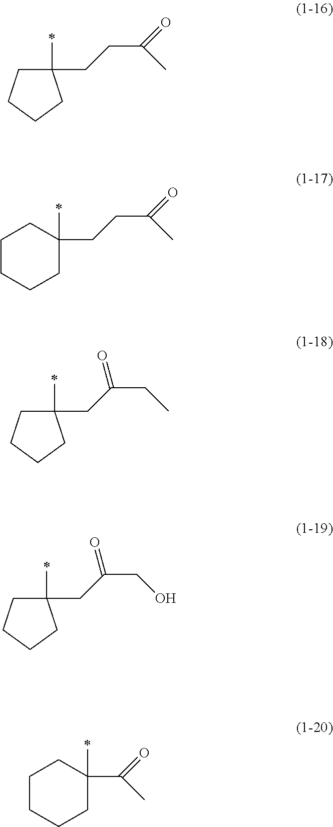

In the above formulae (1-1) to (1-20), * is as defined for the above formula (A).

Of these, the group (1) is preferably the group (1-1), the group (1-3), the group (1-5), the group (1-11), the group (1-12), the group (1-13) or the group (1-14).

Examples of the structural unit (I) include a structural unit represented by the following formula (2-1) (hereinafter, may be also referred to as “structural unit (I-1)”), a structural unit represented by the following formula (2-2) (hereinafter, may be also referred to as “structural unit (1-2)”), and the like.

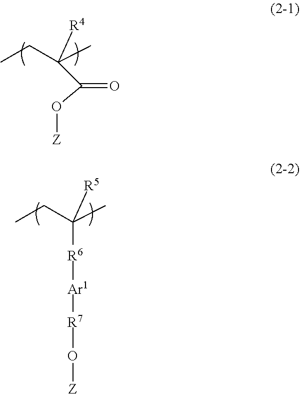

In the above formulae (2-1) and (2-2), Z represents an acid-labile group represented by the above formula (A).

In the above formula (2-1), R⁴ represents a hydrogen atom, a fluorine atom, a methyl group or a trifluoromethyl group.

In the above formula (2-2), R⁵ represents a hydrogen atom or a methyl group; R⁶ represents a single bond, —O—, —COO— or —CONH—; Ar¹ represents a substituted or unsubstituted arenediyl group having 6 to 20 carbon atoms; and R⁷ represents a single bond or —CO—.

R⁴ represents, in light of a degree of copolymerization of a monomer that gives the structural unit (I), preferably a hydrogen atom or a methyl group, and more preferably a methyl group.

R⁵ represents, in light of a degree of copolymerization of the monomer that gives the structural unit (I), a hydrogen atom.

Examples of the arenediyl group having 6 to 20 carbon atoms represented by Ar¹ include a benzenediyl group, an ethylbenzenediyl group, a naphthalenediyl group, an anthracenediyl group, a phenanthrenediyl group, and the like. Examples of the substituent for the arenediyl group include:

alkyl groups having 1 to 5 carbon atoms such as a methyl group, an ethyl group and a propyl group;

cycloalkyl groups having 4 to 8 carbon atoms such as a cyclopentyl group and a cyclohexyl group;

halogen atoms such as a fluorine atom, a chlorine atom, a bromine atom and an iodine atom;

a hydroxy group, a carboxy group, a cyano group, a nitro group, an alkoxy group, an alkoxycarbonyl group, an alkoxycarbonyloxy group, an acyl group, an acyloxy group; and the like.

Ar¹ represents preferably a substituted or unsubstituted benzenediyl group.

R⁶ represents preferably a single bond. R⁷ represents preferably —CO—.

Examples of the structural unit (I-1) include structural units represented by the following formulae (2-1-1) to (2-1-2), and the like. Examples of the structural unit (1-2) include structural units represented by the following formulae (2-2-1) to (2-2-6), and the like.

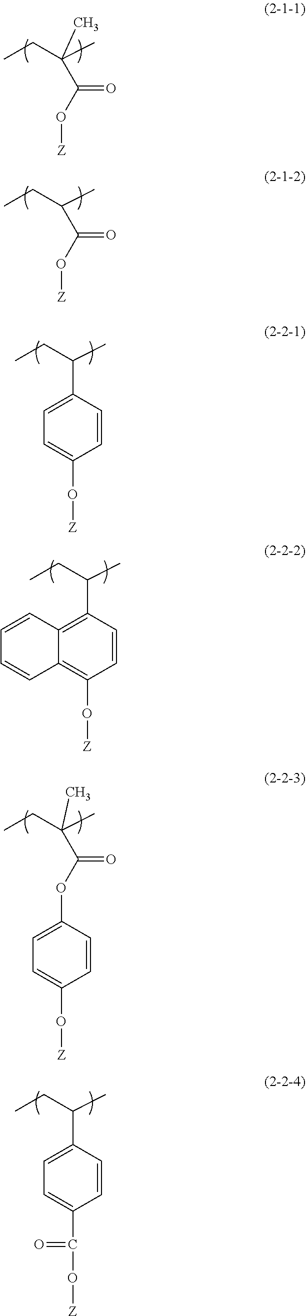

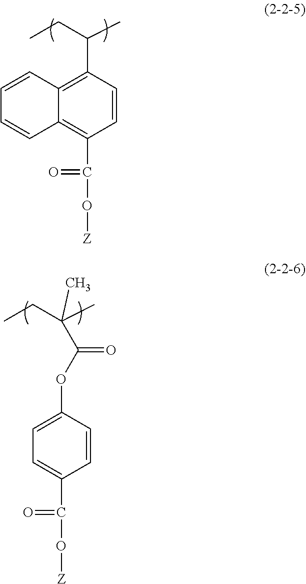

In the above formulae (2-1-1) to (2-2-6), Z is as defined for the above formulae (2-1) and (2-2).

Of these, the structural unit (I) is preferably the structural unit (I-1) or the structural unit (1-2), and more preferably the structural unit represented by the above formula (2-1-1), or the structural unit represented by the above formula (2-2-4).

The lower limit of the proportion of the structural unit (I) contained with respect to the total structural units constituting the polymer (A) is preferably 0.5 mol %, more preferably 2 mol %, and still more preferably 4 mol %. Meanwhile, the upper limit of the proportion of the structural unit (I) contained with respect to the total structural units constituting the polymer (A) is preferably 60 mol %, more preferably 50 mol %, and still more preferably 40 mol %. When the proportion of the structural unit (I) contained falls within the above range, the radiation-sensitive resin composition of the embodiment of the present invention is capable of leading to more improved LWR performance and CDU performance.

The monomer that gives the structural unit (I) is exemplified by a compound (i) having the acid-labile group (1) and a monovalent group that includes a polymerizable carbon-carbon double bond, and the like.

Examples of the monovalent group that includes a polymerizable carbon-carbon double bond include a vinyl group, a propenyl group, a butenyl group, a (meth)acryloyl group, and the like.

The compound (i) is preferably a compound (i-A) represented by the following formula (i-1), or a compound (i-B) represented by the following formula (i-2).

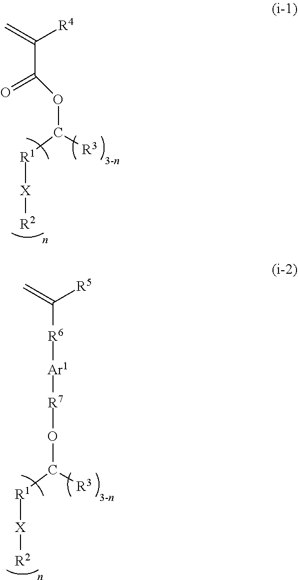

In the above formulae (i-1) and (i-2), X, R¹, R², R³ and n are as defined for the above formula (A).

In the above formula (i-1), R⁴ is as defined for the above formula (2-1).

In the above formula (i-2), R⁵, R⁶, R⁷, and Ar¹ are as defined for the above formula (2-2).

In regard to a synthesis method of the compound (i), for example the compound (i-A) can be synthesized according to the following scheme.

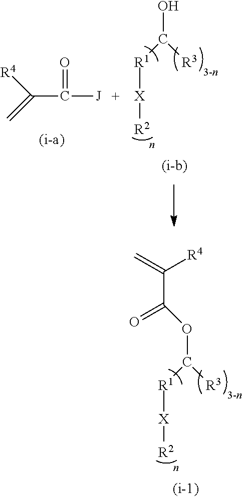

In the above scheme, J represents a halogen atom; and X, R¹, R², R³, R⁴ and n are as defined for the above formula (i-1).

Examples of the halogen atom represented by J include a fluorine atom, a chlorine atom, a bromine atom, an iodine atom, and the like. Of these, a chlorine atom and a bromine atom are preferred, and a chlorine atom is more preferred.

The compound (i-A) represented by the above formula (i-1) may be obtained by allowing the compound represented by the above formula (i-a) including a halogen atom and the monovalent group that includes a polymerizable carbon-carbon double bond to react with a hydroxy compound represented by the above formula (i-b) in the presence of a base such as a triethylamine in a solvent such as methylene chloride. Appropriately purifying thus resulting product by column chromatography, recrystallization, distillation, etc., enables the compound (i-A) to be isolated.

The compound (i) other than the compound (i-A) may be synthesized also in a similar manner.

Structural Unit (II)

The structural unit (II) includes: the acid-labile group (2) other than the acid-labile group (1) included in the structural unit (I); and an oxoacid group protected by the acid-labile group (2), or a phenolic hydroxyl group protected by the acid-labile group (2). Due to the polymer (A) having the structural unit (II), more appropriately adjusting the dissolution contrast between the light-exposed regions and the light-unexposed regions in the resist film to be formed by the radiation-sensitive resin composition of the embodiment of the present invention is enabled, thereby consequently enabling the LWR performance and CDU performance to be to more improved.

The structural unit (II) is preferably represented by the following formula (a-1) or (a-2). In the following formulae (a-1) and (a-2), the groups represented by —CR^{A2}R^{A3}R^{A4} and —CR^{A6}R^{A7}R^{A8} are acid-labile groups.

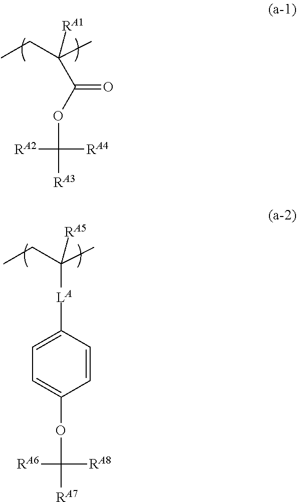

In the above formula (a-1), R^{A1} represents a hydrogen atom, a fluorine atom, a methyl group or a trifluoromethyl group; R^{A2} represents a monovalent hydrocarbon group having 1 to 20 carbon atoms; R^{A3} and R^{A4} each independently represent a monovalent hydrocarbon group having 1 to 20 carbon atoms, or R^{A3} and R^{A4} taken together represent a ring structure having 3 to 20 ring atoms together with the carbon atom to which R^{A3} and R^{A4} bond.

In the above formula (a-2), R^{A5} represents a hydrogen atom, a fluorine atom, a methyl group or a trifluoromethyl group; R^{A6} represents a hydrogen atom, a monovalent hydrocarbon group having 1 to 20 carbon atoms, or a monovalent oxyhydrocarbon group having 1 to 20 carbon atoms; R^{A7} and R^{A8} each independently represent a monovalent hydrocarbon group having 1 to 20 carbon atoms, or a monovalent oxyhydrocarbon group having 1 to 20 carbon atoms; and L^{A} represents a single bond, —O—, —COO— or —CONH—.

The monovalent hydrocarbon group having 1 to 20 carbon atoms which may be represented by R^{A2}, R^{A3}, R^{A4}, R^{A6}, R^{A7} or R^{A8} is exemplified by those similar to the monovalent hydrocarbon groups having 1 to 20 carbon atoms exemplified for R² and R³.

Examples of the ring structure having 3 to 20 ring atoms which may be taken together represented by R^{A3} and R^{A4} together with the carbon atom to which R^{A3} and R^{A4} bond include:

monocyclic alicyclic saturated hydrocarbon structures such as a cyclopropane structure, a cyclobutane structure, a cyclopentane structure, a cyclohexane structure, a cycloheptane structure and a cyclooctane structure;

monocyclic alicyclic unsaturated hydrocarbon structures such as a cyclopropene structure, a cyclobutene structure, a cyclopentene structure, a cyclohexene structure and a cyclooctene structure;

polycyclic alicyclic saturated hydrocarbon structures such as a norbornane structure, an adamantane structure, a tricyclodecane structure and a tetracyclododecane structure;

polycyclic alicyclic unsaturated hydrocarbon structures such as a norbornene structure, a tricyclodecene structure and a tetracyclododecene structure;

aromatic ring structures such as a benzene structure, a naphthalene structure, an anthracene structure and a phenanthrene structure,

monocyclic aliphatic heterocyclic structures such as an oxetane structure, an oxolane structure, an oxane structure and a thiane structure;

polycyclic aliphatic heterocyclic structures such as an oxanorbornane structure, an azanorbornane structure, a thianorbornane structure, a norbornanelactone structure, an oxanorbornanelactone structure and a norbomanesultone structure; and the like.

R^{A2} represents preferably a monovalent chain hydrocarbon group or a cycloalkyl group, more preferably an alkyl group or a cycloalkyl group, and still more preferably a methyl group, an ethyl group, a propyl group, a cyclopentyl group, a cyclohexyl group, a cyclooctyl group or an adamantyl group.

R^{A3} and R^{A4} each represent preferably an alkyl group, and more preferably a methyl group or an ethyl group. The ring structure which may be taken together represented by R^{A3} and R^{A4} together with the carbon atom to which R^{A3} and R^{A4} bond is preferably a monocyclic alicyclic saturated hydrocarbon structure, a norbornane structure or an adamantane structure, and more preferably a cyclopentane structure, a cyclohexane structure or an adamantane structure.

The monovalent oxyhydrocarbon group having 1 to 20 carbon atoms which may be represented by R^{A6}, R^{A7} or R^{A8} is exemplified by groups that include an oxygen atom at the end of the atomic bonding side of the groups exemplified for the monovalent hydrocarbon group having 1 to 20 carbon atoms which may be represented by R² or R³, and the like.

R^{A6}, R^{A7} and R^{A8} each represent preferably the monovalent chain hydrocarbon group or a monovalent oxyalicyclic hydrocarbon group.

L^{A} represents preferably a single bond or —COO—, and more preferably a single bond.

R^{A1} represents, in light of a degree of copolymerization of a monomer that gives the structural unit (II), preferably a hydrogen atom or a methyl group, and more preferably a methyl group.

R^{A5} represents, in light of a degree of copolymerization of the monomer that gives the structural unit (II), preferably a hydrogen atom or a methyl group, and more preferably a hydrogen atom.

Examples of the structural unit (II-1) include structural units represented by the following formulae (a-1-a) to (a-1-d) (hereinafter, may be also referred to as “structural units (II-1-a) to (II-1-d)”), and the like. Furthermore, examples of the structural unit (II-2) include a structural unit represented by the following formula (a-2-a) (hereinafter, may be also referred to as “structural unit (II-2-a)”), and the like.

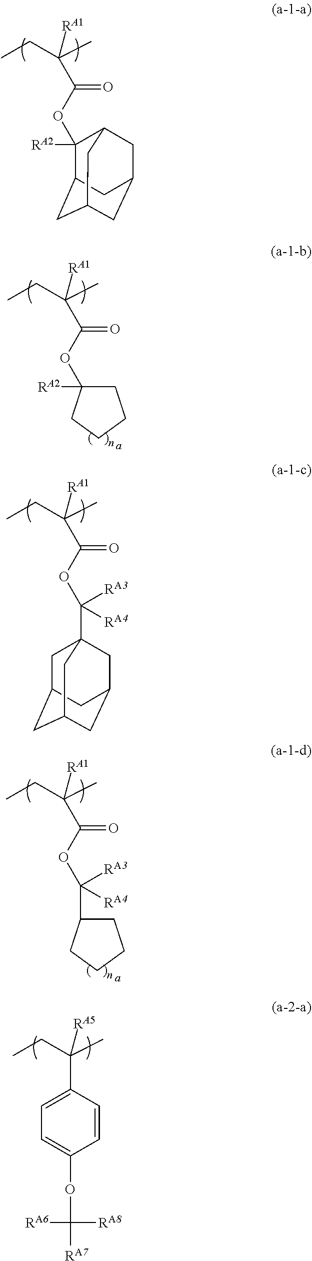

In the above formulae (a-1-a) to (a-1-d), R^{A1} to R^{A4} are as defined for the above formula (a-1); and nₐ is an integer of 1 to 4.

In the above formula (a-2-a), R^{A5} to R^{A8} are as defined for the above formula (a-2).

In the above formulae (a-1-a) to (a-1-d), nₐ is preferably 1, 2 or 4, and more preferably 1.

Examples of the structural units (II-1-a) to (II-1-d) include structural units represented by the following formulae, and the like.

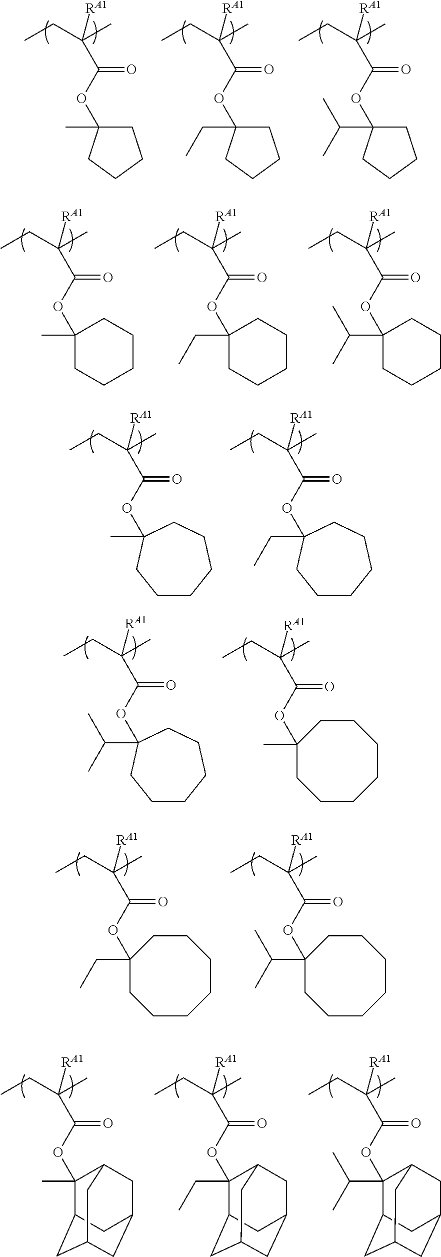

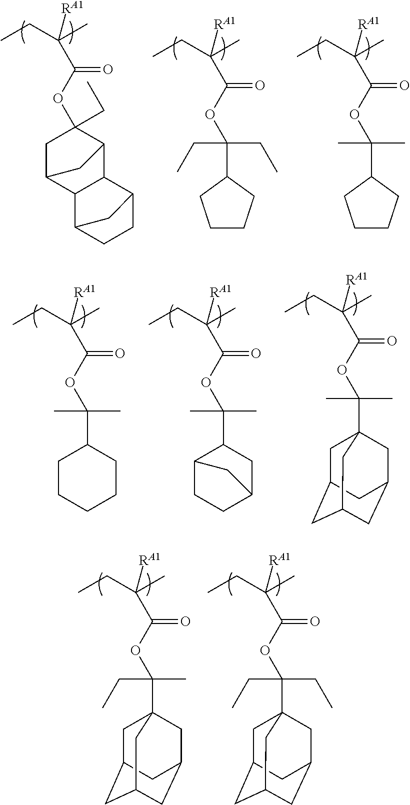

In the above formulae, R^{A1} is as defined for the above formula (a-1).

Examples of the structural unit (II-2-a) include structural units represented by the following formulae, and the like.

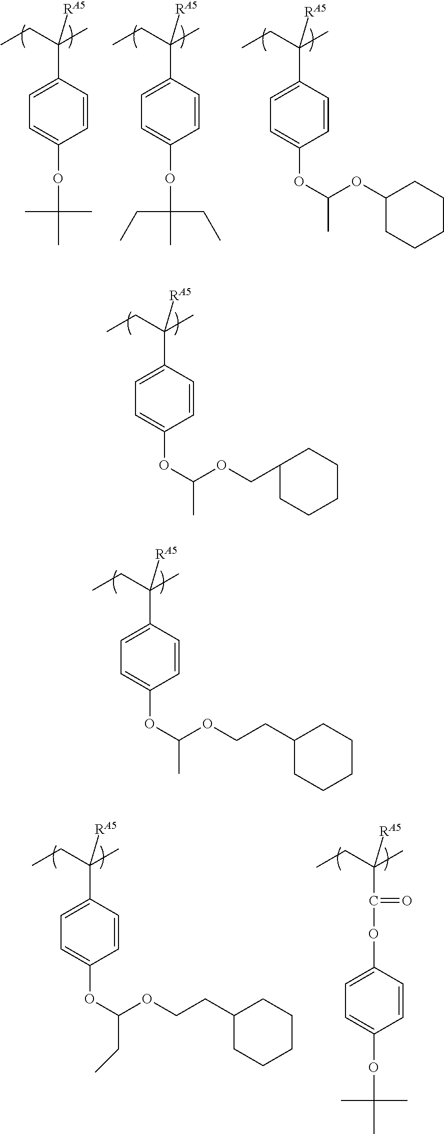

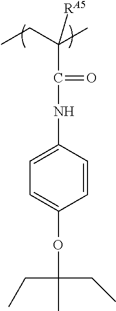

In the above formulae, R^{A5} is as defined for the above formula (a-2).

The structural unit (II) is preferably the structural unit (II-1), more preferably the structural units (II-1-a) to (II-1-d), and still more preferably a structural unit derived from 2-methyl-2-adamantyl (meth)acrylate, a structural unit derived from 2-i-propyl-2-adamantyl (meth)acrylate, a structural unit derived from 1-methyl-1-cyclopentyl (meth)acrylate, a structural unit derived from 1-ethyl-1-cyclohexyl (meth)acrylate, a structural unit derived from 1-i-propyl-1-cyclopentyl (meth)acrylate, a structural unit derived from 2-cyclohexylpropan-2-yl(meth)acrylate, and a structural unit derived from 2-(adamantane-1-yl)propan-2-yl(meth)acrylate.

The lower limit of the proportion of the structural unit (II) contained with respect to the total structural units constituting the polymer (A) is preferably 1 mol %, more preferably 15 mol %, still more preferably 20 mol %, and particularly preferably 30 mol %. Meanwhile, the upper limit of the proportion is preferably 80 mol %, more preferably 70 mol %, and still more preferably 60 mol %. When the proportion falls within the above range, the radiation-sensitive resin composition of the embodiment of the present invention is capable of leading to more improved LWR performance and CDU performance.

The lower limit of the ratio (structural unit (I)/structural unit (II)) of the structural unit (I) to the structural unit (II) constituting the polymer (A) is typically 1/99, and preferably 5/95. Meanwhile, the upper limit of the ratio is typically 50/50, preferably 40/60, and more preferably 30/70.

Structural Unit (III)

The structural unit (III) is a structural unit that includes a lactone structure, a cyclic carbonate structure, a sultone structure or a combination thereof, except for those corresponding to the structural unit (I) and the structural unit (II). When the polymer (A) further has the structural unit (III), more appropriately adjusting the solubility in the developer solution is enabled, thereby consequently enabling the radiation-sensitive resin composition of the embodiment of the present invention to lead to the more improved LWR performance and CDU performance. In addition, the adhesiveness between the substrate and the resist film formed from the radiation-sensitive resin composition can be more improved. The “lactone structure” as referred to herein means a structure having one ring (lactone ring) that includes a group represented by —O—C(O)—. The “cyclic carbonate structure” as referred to herein means a structure having one ring (cyclic carbonate ring) that includes a group represented by —O—C(O)—O—. Further, the “sultone structure” as referred to herein means a structure having one ring (sultone ring) that includes a group represented by —O—S(O)₂—. Examples of the structural unit (III) include structural units represented by the following formulae, and the like.

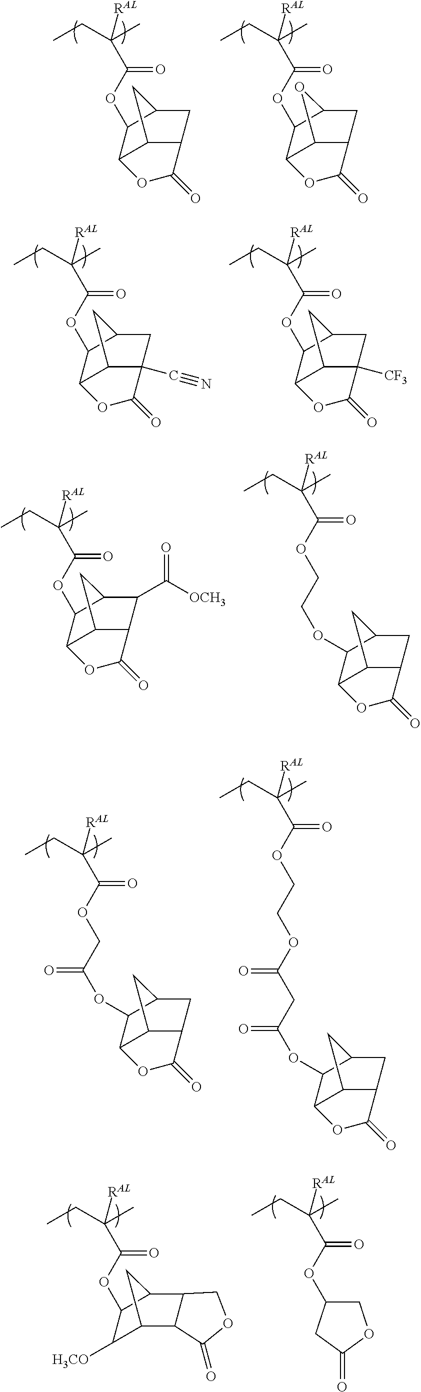

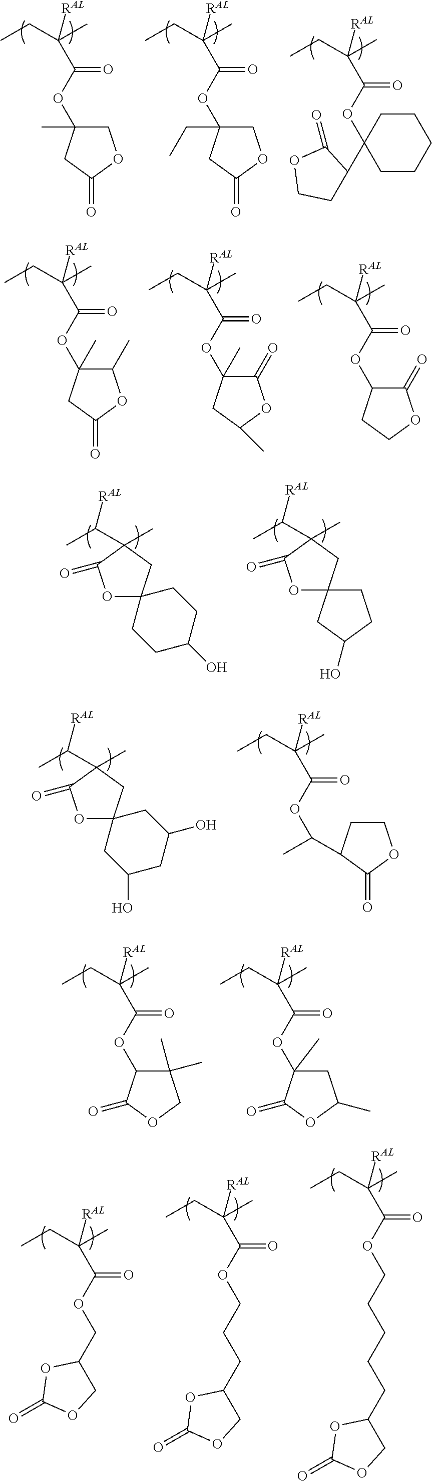

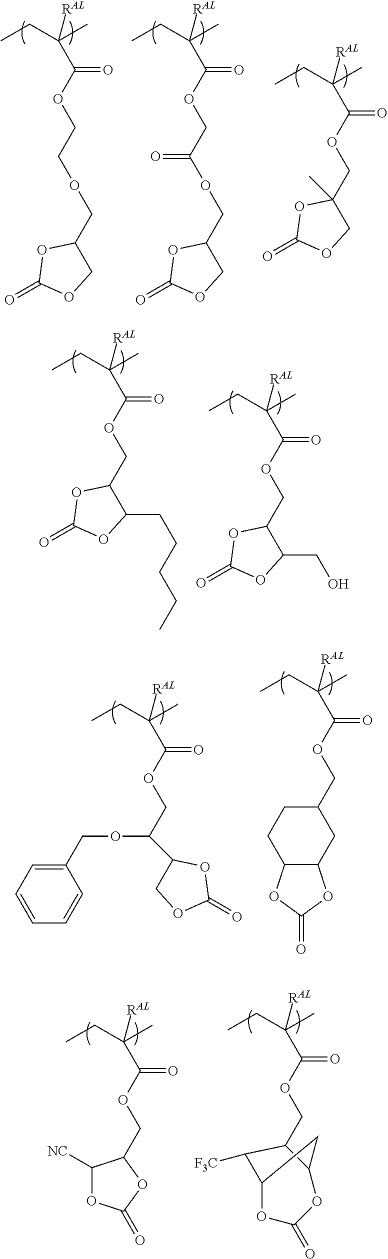

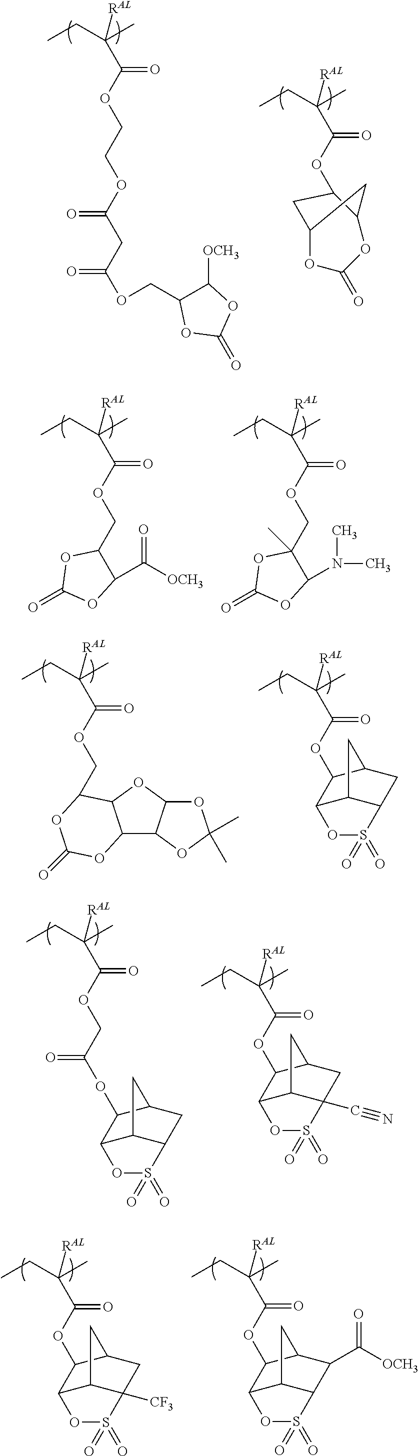

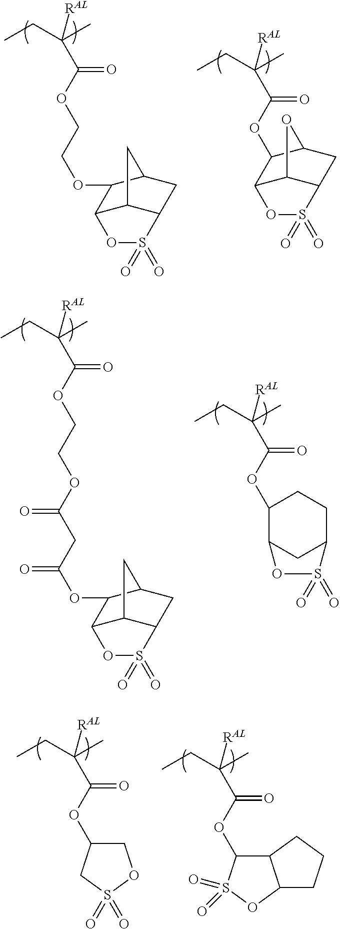

In the above formulae, R^{AL} represents a hydrogen atom, a fluorine atom, a methyl group or a trifluoromethyl group.

R^{AL} represents, in light of a degree of copolymerization of a monomer that gives the structural unit (III), preferably a hydrogen atom or a methyl group, and more preferably a methyl group.

Of these, the structural unit (III) is preferably a structural unit that includes a norbornanelactone structure, a structural unit that includes an oxanorbornanelactone structure, a structural unit that includes a γ-butyrolactone structure, a structural unit that includes an ethylenecarbonate structure, or a structural unit that includes a norbornanesultone structure, and more preferably a structural unit derived from norbomanelactone-yl (meth)acrylate, a structural unit derived from oxanorbornanelactone-yl (meth)acrylate, a structural unit derived from cyano-substituted norbomanelactone-yl (meth)acrylate, a structural unit derived from norbornanelactone-yloxycarbonylmethyl (meth)acrylate, a structural unit derived from butyrolactone-3-yl (meth)acrylate, a structural unit derived from butyrolactone-4-yl (meth)acrylate, a structural unit derived from 3,5-dimethylbutyrolactone-3-yl (meth)acrylate, a structural unit derived from 4,5-dimethylbutyrolactone-4-yl (meth)acrylate, a structural unit derived from 1-(butyrolactone-3-yl)cyclohexan-1-yl (meth)acrylate, a structural unit derived from ethylenecarbonate-ylmethyl (meth)acrylate, a structural unit derived from cyclohexenecarbonate-ylmethyl (meth)acrylate, a structural unit derived from norbornanesultone-yl (meth)acrylate, or a structural unit derived from norbornanesultone-yloxycarbonyl methyl(meth)acrylate.

In a case in which the polymer (A) has the structural unit (III), the lower limit of the proportion of the structural unit (III) contained with respect to the total structural units constituting the polymer (A) is preferably 1 mol %, more preferably 10 mol %, still more preferably 30 mol %, and particularly preferably 40 mol %. Meanwhile, the upper limit of the proportion is preferably 80 mol %, more preferably 70 mol %, and still more preferably 60 mol %. When the proportion falls within the above range, the adhesiveness between the substrate and the resist film formed from the radiation-sensitive resin composition of the embodiment of the present invention can be more improved. When the proportion is less than the lower limit, the adhesiveness between the substrate and the resist film formed from the radiation-sensitive resin composition may be lowered. To the contrary, when the proportion is greater than the upper limit, pattern formability of the radiation-sensitive resin composition may be impaired.

Structural Unit (IV)

The structural unit (IV) is a structural unit that includes a phenolic hydroxyl group, except for those corresponding to the structural unit (I) to structural unit (III). When the polymer (A) has the structural unit (IV), improving the sensitivity is enabled in a case in which irradiation with a KrF excimer laser beam, EUV (extreme ultraviolet ray), an electron beam or the like is performed in an exposure step described later.

Examples of the structural unit (IV) include a structural unit represented by the following formula (af), and the like.

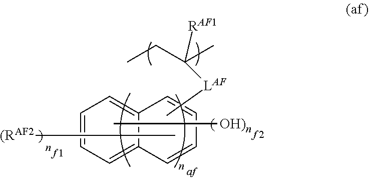

In the above formula (af), R^{AF1} represents a hydrogen atom or a methyl group; L^{AF} represents a single bond, —COO—, —O— or —CONH—; R^{AF2} represents a monovalent organic group having 1 to 20 carbon atoms; n_{f1} is an integer of 0 to 3, wherein in a case in which n_{f1} is 2 or 3, a plurality of R^{AF2}s may be identical or different; n_{f2} is an integer of 1 to 3, wherein (n_{f1}+n_{f2}) is no greater than 5; and n_{AF} is an integer of 0 to 2.

R^{AF1} represents, in light of a degree of copolymerization of a monomer that gives the structural unit (IV), preferably a hydrogen atom.

L^{AF} represents preferably a single bond or —COO—.

The monovalent organic group having 1 to 20 carbon atoms represented by R^{AF2} is exemplified by: a monovalent hydrocarbon group having 1 to 20 carbon atoms; a group that includes a divalent heteroatom-containing group between two adjacent carbon atoms or at the end of the atomic bonding side of the hydrocarbon group; a group obtained by substituting with a monovalent heteroatom-containing group, a part or all of hydrogen atoms included in the hydrocarbon group or the divalent heteroatom-containing group, and the like.

The monovalent hydrocarbon group having 1 to 20 carbon atoms is exemplified by those similar to the monovalent hydrocarbon group having 1 to 20 carbon atoms exemplified for R² and R³, and the like. The divalent heteroatom-containing group which may be included between two adjacent carbon atoms or at the end of the atomic bonding side of the hydrocarbon group is exemplified by —O—, —S—, —NR″—, —CO—, —COO—, —CS—, and the like, wherein R″ represents a hydrogen atom or a monovalent hydrocarbon group having 1 to 10 carbon atoms. The monovalent heteroatom-containing group is exemplified by —OH, —SH, —CN, —NHR″, —COR″, —CSR″, and the like.

R^{AF2} represents preferably the monovalent chain hydrocarbon group, more preferably the alkyl group, and still more preferably a methyl group.

In the above formula (af), n_{f1} is preferably an integer of 0 to 2, more preferably 0 or 1, and still more preferably 0.

In the above formula (af), n_{f2} is preferably 1 or 2, and more preferably 1.

In the above formula (af), n_{AF} is preferably 0 or 1, and more preferably 0.

Examples of the structural unit (IV) include structural units represented by the following formulae (f-1) to (f-6) (hereinafter, may be also referred to as “structural units (IV-1) to (IV-6)”), and the like.

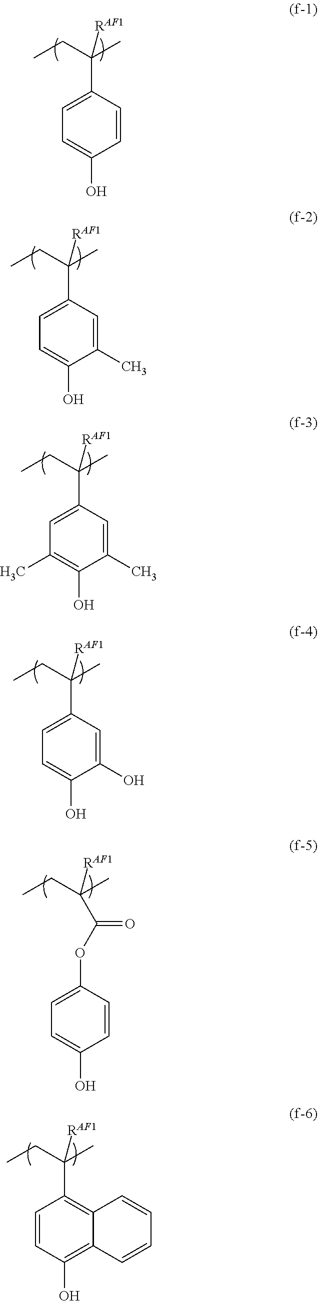

In the above formulae (f-1) to (f-6), R^{AF1} is as defined for the above formula (af).

The structural unit (IV-1) is preferably the structural units (IV-1) or (IV-2), and more preferably the structural unit (IV-1).

The structural unit (IV) may be formed by, for example, a process including: substituting a hydrogen atom of an —OH group in a hydroxystyrene with an acetyl group or the like to give a monomer; polymerizing the monomer; and then a polymer thus obtained is subjected to a hydrolysis reaction in the presence of an amine, or the like.

In a case in which the polymer (A) has the structural unit (IV), the lower limit of the proportion of the structural unit (IV) contained with respect to the total structural units constituting the polymer (A) is preferably 1 mol %, more preferably 15 mol %, and still more preferably 30 mol %. Meanwhile, the upper limit of the proportion is preferably 90 mol %, more preferably 70 mol %, and still more preferably 50 mol %. When the proportion of the structural unit (IV) falls within the above range, a more improvement of the sensitivity of the radiation-sensitive resin composition of the embodiment of the present invention is enabled.

Structural Unit (V)

The structural unit (V) is a structural unit that includes an alcoholic hydroxyl group, except for those corresponding to the structural units (I) to (IV). When the polymer (A) further has the structural unit (V), more appropriately adjusting the solubility in the developer solution is enabled, thereby consequently enabling the radiation-sensitive resin composition to lead to the more improved LWR performance and CDU performance. In addition, the adhesiveness between the substrate and the resist pattern formed from the radiation-sensitive resin composition of the embodiment of the present invention can be more improved.

Examples of the structural unit (V) include structural units represented by the following formulae, and the like.

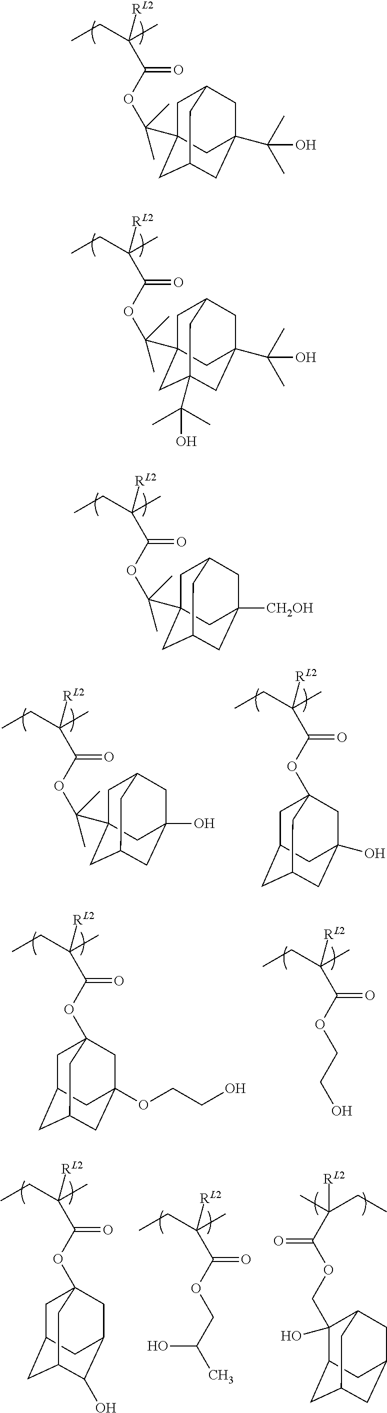

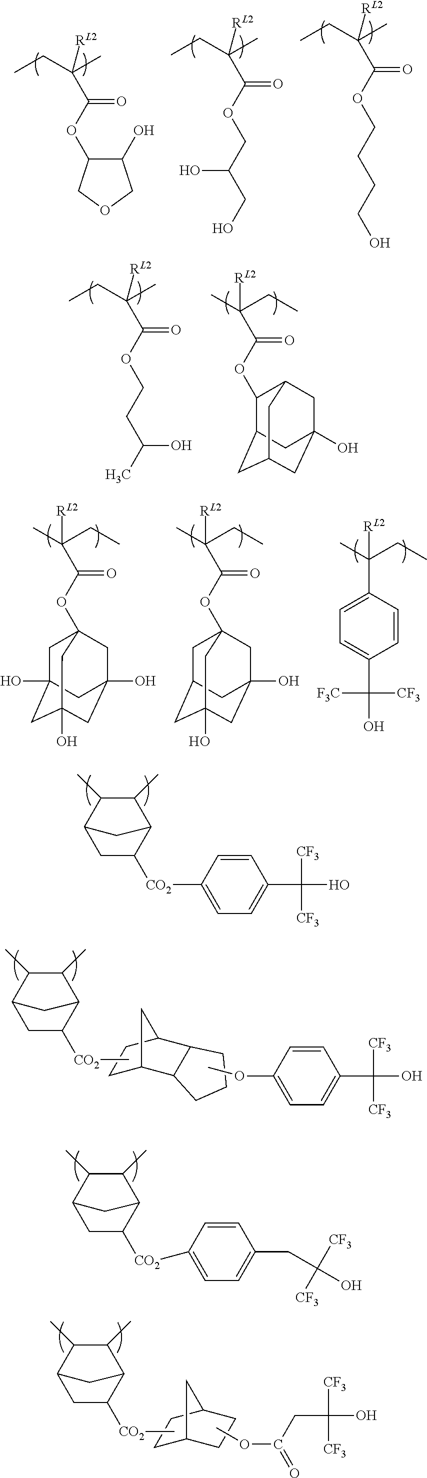

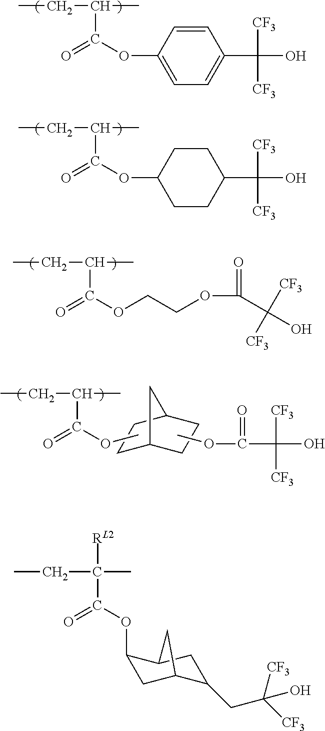

In the above formulae, R^{L2} represents a hydrogen atom, a fluorine atom, a methyl group or a trifluoromethyl group.

Of these, a structural unit derived from 3-hydroxyadamantan-1-yl (meth)acrylate is preferred.

In a case in which the polymer (A) has the structural unit (V), the lower limit of the proportion of the structural unit (V) contained with respect to the total structural units constituting the polymer (A) is preferably 1 mol %, more preferably 8 mol %, still more preferably 30 mol %, and particularly preferably 40 mol %. Meanwhile, the upper limit of the proportion is preferably 70 mol %, more preferably 60 mol %, and still more preferably 50 mol %. When the proportion of the structural unit (V) falls within the above range, more appropriately adjusting the solubility of the polymer (A) in the developer solution is enabled.

Other Structural Unit

The polymer (A) may have other structural unit in addition to the structural units (I) to (V). The other structural unit is exemplified by a structural unit that includes a carboxy group, a cyano group, a nitro group, a sulfonamide group or the like. The upper limit of the proportion of the other structural unit contained with respect to the total structural units constituting the polymer (A) is preferably 20 mol %, and more preferably 10 mol %.

### Synthesis Procedure of Polymer (A)

The polymer (A) may be synthesized by, for example, polymerizing a monomer that gives each structural unit in the presence of a radical polymerization initiator or the like in a suitable solvent.

Specific examples of the radical polymerization initiator and the solvent used in the polymerization for the polymer (A) include compounds disclosed in paragraphs [0181] to [0182] of Japanese Unexamined Patent Application, Publication No. 2017-090674, and the like.

The lower limit of the reaction temperature in the polymerization for the polymer (A) is preferably 40° C., and more preferably 50° C. Meanwhile, the upper limit of the reaction temperature is preferably 150° C., and more preferably 120° C. The lower limit of the reaction time period in the polymerization for the polymer (A) is preferably 1 hr, and more preferably 2 hrs. Meanwhile, the upper limit of the reaction time period is preferably 48 hrs, and more preferably 24 hrs.

The lower limit of the weight average molecular weight (Mw) of the polymer (A) is preferably 1,000, more preferably 3,000, and still more preferably 5,000. Meanwhile, the upper limit of the Mw is preferably 50,000, more preferably 20,000, and still more preferably 8,000. When the Mw falls within the above range, an application property of the radiation-sensitive resin composition of the embodiment of the present invention can be improved.

The lower limit of the ratio (Mw/Mn) of the Mw to the number average molecular weight (Mn) of the polymer (A) is typically 1, and preferably 1.3. Meanwhile, the upper limit of the Mw/Mn is preferably 5, more preferably 3, still more preferably 2, and particularly preferably 1.8. When the Mw/Mn falls within the above range, the radiation-sensitive resin composition is capable of leading to more improved LWR performance and CDU performance.

As used herein, the Mw and the Mn of the polymer are determined using gel permeation chromatography (GPC) under the following conditions.

GPC columns: for example, “G2000 HXL” 2, “G3000 HXL”×1, and “G4000 HXL”×1 available from Tosoh Corporation;

column temperature: 40° C.;

elution solvent: tetrahydrofuran;

flow rate: 1.0 mL/min;

sample concentration: 1.0% by mass;

amount of injected sample: 100 μL;

detector: differential refractometer; and

standard substance: mono-dispersed polystyrene.

The lower limit of the content of the polymer (A) with respect to the total polymer contained in the radiation-sensitive resin composition of the embodiment of the present invention is preferably 60% by mass, more preferably 70% by mass, and still more preferably 90% by mass. When the content is no less than the lower limit, the radiation-sensitive resin composition is capable of leading to more improved LWR performance and CDU performance.

The lower limit of the content of the polymer (A) in the radiation-sensitive resin composition of the embodiment of the present invention in terms of solid content equivalent is preferably 50% by mass, more preferably 60% by mass, and still more preferably 70% by mass. Meanwhile, the upper limit of the content in terms of solid content equivalent is preferably 99% by mass, more preferably 95% by mass, and still more preferably 90% by mass. When the content falls within the above range, the radiation-sensitive resin composition is capable of leading to more improved LWR performance and CDU performance. The “solid content” as referred to herein means components in the radiation-sensitive resin composition, other than the solvent (C) and a localization accelerator described later.

### (B) Acid Generator

The acid generator (B) is a substance that generates an acid upon an exposure. The acid thus generated allows the acid-labile group included in the polymer (A) or the like to be dissociated, thereby generating a carboxy group, etc. As a result, the solubility of the polymer (A) and the like in the developer solution changes, and thus formation of a resist pattern from the radiation-sensitive resin composition of the embodiment of the present invention is enabled. The acid generator (B) may be contained in the radiation-sensitive resin composition either in the form of a low-molecular-weight compound (hereinafter, may be also referred to as “(B) acid generating agent” or “acid generating agent (B)”) described below or in the form of an acid generator incorporated as a part of the polymer, or may be in both of these forms. The radiation-sensitive resin composition may contain one, or two or more types of the acid generator (B).

The acid generating agent (B) is exemplified by an onium salt compound, an N-sulfonyloxyimide compound, a halogen-containing compound, a diazo ketone compound, and the like.

Exemplary onium salt compound includes a sulfonium salt, a tetrahydrothiophenium salt, an iodonium salt, a phosphonium salt, a diazonium salt, a pyridinium salt, and the like.

Specific examples of the acid generating agent (B) include compounds disclosed in paragraphs [0080] to [0113] of Japanese Unexamined Patent Application, Publication No. 2009-134088, and the like.

The acid generating agent (B) is preferably a compound represented by the following formula (b). When the acid generating agent (B) has the following structure, it is expected that a diffusion length in the resist film, of the acid generated upon the exposure will be properly reduced through e.g., an interaction with the polymer (A), and as a result, the radiation-sensitive resin composition of the embodiment of the present invention would be capable of leading to more improved LWR performance and CDU performance.

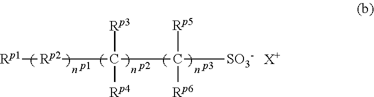

In the above formula (b), R^{p1} represents a monovalent group that includes a ring structure having no less than 6 ring atoms; R^{p2} represents a divalent linking group; R^{p3} and R^{p4} each independently represent a hydrogen atom, a fluorine atom, a monovalent hydrocarbon group having 1 to 20 carbon atoms or a monovalent fluorinated hydrocarbon group having 1 to 20 carbon atoms; R^{p5} and R^{p6} each independently represent a fluorine atom or a monovalent fluorinated hydrocarbon group having 1 to 20 carbon atoms; n^{p1} is an integer of 0 to 10; n^{p2} is an integer of 0 to 10; n^{p3} is an integer of 1 to 10; and X⁺ represents a monovalent radiation-sensitive onium cation, wherein: in a case in which n^{p1} is no less than 2, a plurality of R^{p2}s may be identical or different; in a case in which n^{p2} is no less than 2, a plurality of R^{p3} may be identical or different, and a plurality of R^{p4} may be identical or different; and in a case in which n^{p3} is no less than 2, a plurality of R^{P5}s may be identical or different, and a plurality of R^{p6} may be identical or different.

The monovalent group that includes a ring structure having no less than 6 ring atoms represented by R^{p1} is exemplified by a monovalent group that includes a ring structure having no less than 6 ring atoms, a monovalent group that includes an alicyclic structure having no less than 6 ring atoms, a monovalent group that includes an aliphatic heterocyclic structure having no less than 6 ring atoms, a monovalent group that includes an aromatic ring structure having no less than 6 ring atoms, a monovalent group that includes an aromatic heterocyclic structure having no less than 6 ring atoms, and the like.

Examples of the alicyclic structure having no less than 6 ring atoms include:

monocyclic alicyclic saturated hydrocarbon structures such as a cyclohexane structure, a cycloheptane structure, a cyclooctane structure, a cyclononane structure, a cyclodecane structure and a cyclododecane structure;

monocyclic alicyclic unsaturated hydrocarbon structures such as a cyclohexene structure, a cycloheptene structure, a cyclooctene structure and a cyclodecene structure;

polycyclic alicyclic saturated hydrocarbon structures such as a norbornane structure, an adamantane structure, a tricyclodecane structure and a tetracyclododecane structure;

polycyclic alicyclic unsaturated hydrocarbon structures such as a norbornene structure and a tricyclodecene structure; and the like.

Examples of the aliphatic heterocyclic structure having no less than 6 ring atoms include:

lactone structures such as a hexanolactone structure and a norbomanelactone structure;

sultone structures such as a hexanosultone structure and a norbornanesultone structure;

oxygen atom-containing heterocyclic structures such as an oxacycloheptane structure and an oxanorbornane structure;

nitrogen atom-containing heterocyclic structures such as an azacyclohexane structure and a diazabicyclooctane structure;

sulfur atom-containing heterocyclic structures such as a thiacyclohexane structure and a thianorbornane structure; and the like.

Examples of the aromatic ring structure having no less than 6 ring atoms include a benzene structure, a naphthalene structure, a phenanthrene structure, an anthracene structure, and the like.

Examples of the aromatic heterocyclic structure having no less than 6 ring atoms include:

oxygen atom-containing heterocyclic structures such as a pyran structure and a benzopyran structure;

nitrogen atom-containing heterocyclic structures such as a pyridine structure, a pyrimidine structure and an indole structure; and the like.

The lower limit of the number of ring atoms of the ring structure included in R^{p1} is preferably 7, more preferably 8, still more preferably 9, and particularly preferably 10. Meanwhile, the upper limit of the number of ring atoms is preferably 15, more preferably 14, still more preferably 13, and particularly preferably 12. When the number of ring atoms falls within the above range, the aforementioned diffusion length of the acid may be further properly reduced, and as a result, the radiation-sensitive resin composition of the embodiment of the present invention is capable of leading to more improved LWR performance and CDU performance. A part or all of hydrogen atoms included in the ring structure of R^{p1} may be substituted with a substituent. Examples of the substituent include halogen atoms such as a fluorine atom, a chlorine atom, a bromine atom and an iodine atom, a hydroxy group, a carboxy group, a cyano group, a nitro group, an alkoxy group, an alkoxycarbonyl group, an alkoxycarbonyloxy group, an acyl group, an acyloxy group, and the like. Of these, the hydroxy group is preferred.

Of these, R^{p1} represents preferably a monovalent group that includes an alicyclic structure having no less than 6 ring atoms or a monovalent group that includes an aliphatic heterocyclic structure having no less than 6 ring atoms, more preferably a monovalent group that includes an alicyclic structure having no less than 9 ring atoms or a monovalent group that includes an aliphatic heterocyclic structure having no less than 9 ring atoms, still more preferably an adamantyl group, a hydroxyadamantyl group, a norbornanelactone-yl group, a norbornanesultone-yl group or a 5-oxo-4-oxatricyclo[4.3.1.1^{3,8}]undecan-yl group, and particularly preferably an adamantyl group.

Examples of the divalent linking group represented by R^{p2} include a carbonyl group, an ether group, a carbonyloxy group, a sulfide group, a thiocarbonyl group, a sulfonyl group, a divalent hydrocarbon group, and the like. The divalent linking group represented by R^{p2} is preferably the carbonyloxy group, the sulfonyl group, an alkanediyl group or a cycloalkanediyl group, more preferably the carbonyloxy group or the cycloalkanediyl group, still more preferably the carbonyloxy group or a norbornanediyl group, and particularly preferably the carbonyloxy group.

The monovalent hydrocarbon group having 1 to 20 carbon atoms which may be represented by R^{p3} or R^{p4} is exemplified by an alkyl group having 1 to 20 carbon atoms, and the like. The monovalent fluorinated hydrocarbon group having 1 to 20 carbon atoms which may be represented by R^{p3} or R^{p4} is exemplified by a fluorinated alkyl group having 1 to 20 carbon atoms, and the like. R^{p3} and R^{p4} each independently represent preferably a hydrogen atom, a fluorine atom or a fluorinated alkyl group, more preferably a fluorine atom or a perfluoroalkyl group, and still more preferably a fluorine atom or a trifluoromethyl group.

The monovalent fluorinated hydrocarbon group having 1 to 20 carbon atoms which may be represented by R^{p5} or R^{p6} is exemplified by a fluorinated alkyl group having 1 to 20 carbon atoms, and the like. R^{p5} and R^{p6} each independently represent preferably a fluorine atom or a fluorinated alkyl group, more preferably a fluorine atom or a perfluoroalkyl group, still more preferably a fluorine atom or a trifluoromethyl group, and particularly preferably a fluorine atom.

In the above formula (b), n^{p1} is preferably an integer of 0 to 5, more preferably an integer of 0 to 3, still more preferably an integer of 0 to 2, and particularly preferably 0 or 1.

In the above formula (b), n^{p2} is preferably an integer of 0 to 5, more preferably an integer of 0 to 2, still more preferably 0 or 1, and particularly preferably 0.

In the above formula (b), n^{p3} is preferably an integer of 1 to 5, more preferably an integer of 1 to 4, still more preferably an integer of 1 to 3, and particularly preferably 1 or 2.

The monovalent radiation-sensitive onium cation represented by X⁺ is a cation that is degraded upon an irradiation with exposure light. At the light-exposed regions, a sulfonic acid is generated from the sulfonate anion and a proton generated through degradation of the light-labile onium cation. Examples of the monovalent radiation-sensitive onium cation represented by X⁺ include: a cation represented by the following formula (b-a) (hereinafter, may be also referred to as “cation (b-a)”), a cation represented by the following formula (b-b) (hereinafter, may be also referred to as “cation (b-b)”), a cation represented by the following formula (b-c) (hereinafter, may be also referred to as “cation (b-c)”), and the like.

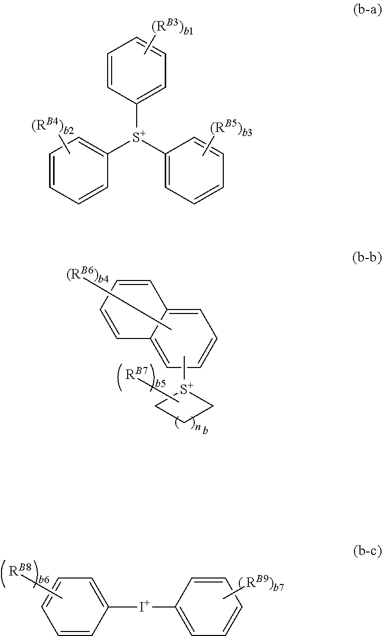

In the above formula (b-a), R^{B3}, R^{B4} and R^{B5} each independently represent a substituted or unsubstituted linear or branched alkyl group having 1 to 12 carbon atoms, a substituted or unsubstituted aromatic hydrocarbon group having 6 to 12 carbon atoms, —OSO₂—R^{BB1} or —SO₂—R^{BB2}, or at least two of R^{B3}, R^{B4} and R^{B5} taken together represent a ring structure, and the rest of R^{B3}, R^{B4} and R^{B5} represents a substituted or unsubstituted linear or branched alkyl group having 1 to 12 carbon atoms, a substituted or unsubstituted aromatic hydrocarbon group having 6 to 12 carbon atoms, —OSO₂—R^{BB1} or —SO₂—R^{BB2}, wherein R^{BB1} and R^{BB2} each independently represent a substituted or unsubstituted linear or branched alkyl group having 1 to 12 carbon atoms, a substituted or unsubstituted alicyclic hydrocarbon group having 5 to 25 carbon atoms, or a substituted or unsubstituted aromatic hydrocarbon group having 6 to 12 carbon atoms; and b1, b2 and b3 are each independently an integer of 0 to 5, wherein in a case in which R^{B3} to R^{B5}, R^{BB1} and R^{BB2} are each present in a plurality of number, a plurality of R^{B3}s may be identical or different with each other, a plurality of R^{B4}s may be identical or different with each other, a plurality of R^{B}Ss may be identical or different with each other, a plurality of R^{BB1}s may be identical or different with each other, and a plurality of R^{BB2}s may be identical or different with each other.

In the above formula (b-b), R^{B6} represents a substituted or unsubstituted linear or branched alkyl group having 1 to 8 carbon atoms, or a substituted or unsubstituted aromatic hydrocarbon group having 6 to 8 carbon atoms; b4 is an integer of 0 to 7, wherein in a case in which R^{b6} is present in a plurality of number, a plurality of R^{b6}s may be identical or different with each other, or the plurality of R^{b6}s may taken together represent a ring structure; R^{b7} represents a substituted or unsubstituted linear or branched alkyl group having 1 to 7 carbon atoms, or a substituted or unsubstituted aromatic hydrocarbon group having 6 or 7 carbon atoms; b5 is an integer of 0 to 6, wherein in a case in which R^{b7} is present in a plurality of number, a plurality of R^{b7}s may be identical or different with each other, or the plurality of R^{b7}s may taken together represent a ring structure; n_{b2} is an integer of 0 to 3; R^{B8} represents a single bond or divalent organic group having 1 to 20 carbon atoms; and n_{b1} is an integer of 0 to 2.

In the above formula (b-c), R^{B9} and R^{B10} each independently represent a substituted or unsubstituted linear or branched alkyl group having 1 to 12 carbon atoms, a substituted or unsubstituted aromatic hydrocarbon group having 6 to 12 carbon atoms, —OSO₂—R^{BB3} or —SO₂—R^{BB4}, or at least two of these groups may taken together represent a ring structure, wherein R^{BB3} and R^{BB4} each independently represent a substituted or unsubstituted linear or branched alkyl group having 1 to 12 carbon atoms, a substituted or unsubstituted alicyclic hydrocarbon group having 5 to 25 carbon atoms or a substituted or unsubstituted aromatic hydrocarbon group having 6 to 12 carbon atoms; b6 and b7 are each independently an integer of 0 to 5, wherein in a case in which R^{B9}, R^{B10}, R^{BB3} and R^{BB4} are each present in a plurality of number, a plurality of R^{B9}s may be identical or different with each other, a plurality of R^{B10}s may be identical or different with each other, a plurality of R^{BB3}s may be identical or different with each other, and a plurality of R^{BB4}s may be identical or different with each other.

Examples of the unsubstituted linear alkyl group which may be represented by R^{B3}, R^{B4}, RB, R^{B6}, R^{B7}, R^{B9} or R^{B10} include a methyl group, an ethyl group, a n-propyl group, a n-butyl group, and the like.

Examples of the unsubstituted branched alkyl group which may be represented by R^{B3}, R^{B4}, R^{B5}, R^{B6}, R^{B7}, R^{B9} or R¹⁰ include an i-propyl group, an i-butyl group, a sec-butyl group, a t-butyl group, and the like.

Examples of the unsubstituted aromatic hydrocarbon group which may be represented by R^{B3}, R^{B4}, R^{B5}, R^{B9} or R^{B10} include:

aryl groups such as a phenyl group, a tolyl group, a xylyl group, a mesityl group and a naphthyl group;

aralkyl groups such as a benzyl group and a phenethyl group; and the like.

Examples of the unsubstituted aromatic hydrocarbon group which may be represented by R^{B6} or R^{B7} include a phenyl group, a tolyl group, a benzyl group, and the like.

The divalent organic group which may be represented by R^{B8} is exemplified by a divalent organic group having 1 to 20 carbon atoms, and the like.

Examples of the substituent which may substitute for a hydrogen atom included in the alkyl group or aromatic hydrocarbon group include halogen atoms such as a fluorine atom, a chlorine atom, a bromine atom and an iodine atom, a hydroxy group, a carboxy group, a cyano group, a nitro group, an alkoxy group, an alkoxycarbonyl group, an alkoxycarbonyloxy group, an acyl group, an acyloxy group, and the like. Of these, the halogen atoms are preferred, and the fluorine atom is more preferred.

R^{B3}, R^{B4}, R^{B}, R^{B6}, R^{B7}, R^{B9} and R^{B10} each independently represent preferably an unsubstituted linear or branched alkyl group, a fluorinated alkyl group, an unsubstituted monovalent aromatic hydrocarbon group, —OSO₂—R^{BB5} or —SO₂—R^{BB5}, more preferably a fluorinated alkyl group or an unsubstituted monovalent aromatic hydrocarbon group, and still more preferably a fluorinated alkyl group, wherein R^{BB5} represents an unsubstituted monovalent alicyclic hydrocarbon group or an unsubstituted monovalent aromatic hydrocarbon group.

In the above formula (b-a), b1, b2 and b3 are each preferably an integer of 0 to 2, more preferably 0 or 1, and still more preferably 0. In the formula (b-b), b4 is preferably an integer of 0 to 2, more preferably 0 or 1, and still more preferably 1. As b5, an integer of 0 to 2 is preferred, 0 and 1 are more preferred, and 0 is still more preferred. As n_{b2}, 2 and 3 are preferred, and 2 is more preferred. As n_{b1}, 0 and 1 are preferred, and 0 is more preferred. In the formula (b-c), b6 and b7 are each preferably an integer of 0 to 2, more preferably 0 or 1, and still more preferably 0.

X⁺ represents preferably a cation (b-a) or a cation (b-b), and more preferably a triphenylsulfonium cation or a 1-[2-(4-cyclohexylphenylcarbonyl)propan-2-yl]tetrahydrothiophenium cation.

Examples of the acid generating agent represented by the above formula (b) include compounds represented by the following formulae (b-1) to (b-15) (hereinafter, may be also referred to as “compound (b-1) to (b-15)”), and the like.

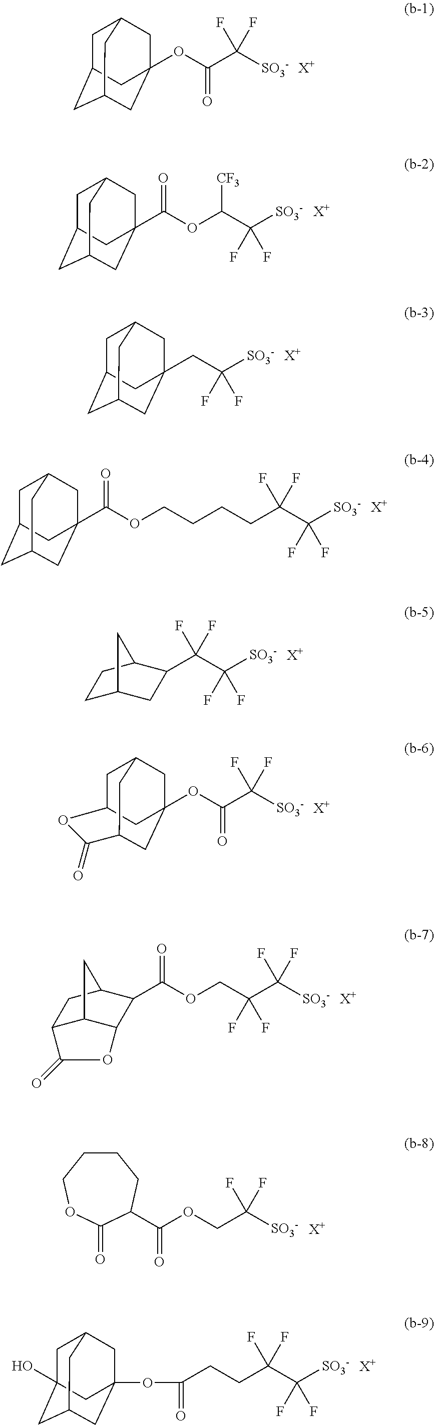

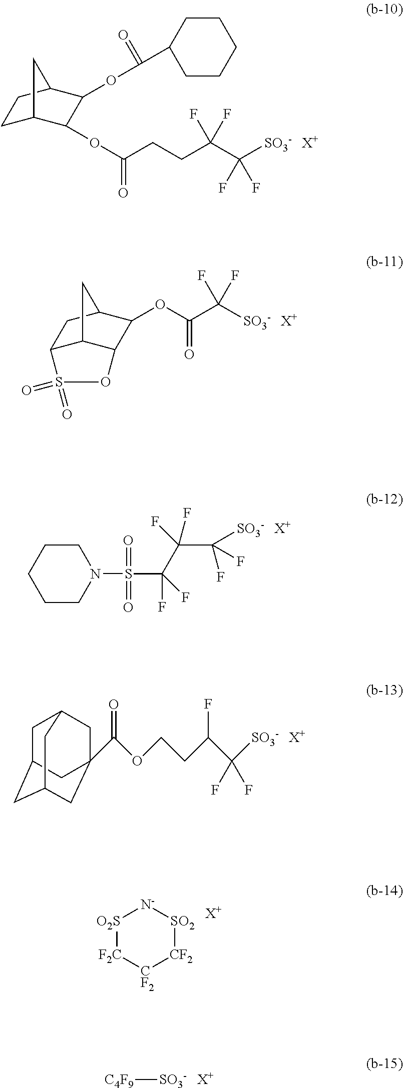

In the above formulae (b-1) to (b-15), X⁺ represents a monovalent radiation-sensitive onium cation.

The acid generating agent (B) is preferably the onium salt compound, and more preferably the compound (b-5), (b-14) or (b-15). Furthermore, a polymer having a structural unit represented by the following formula (7) is also preferred as the acid generator (B). The structural unit may be included in the polymer (A), or may be included in other polymer. It is to be noted that in a case in which the polymer (A) has the structural unit described above, the polymer (A) serves also as the acid generator (B).

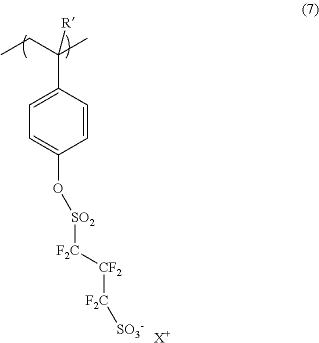

In the above formula (7), R′ represents a hydrogen atom or a methyl group; and X⁺ represents a monovalent radioactive ray-labile onium cation.

In a case in which the acid generator (B) is the acid generating agent (B), the lower limit of the content of the acid generating agent (B) with respect to 100 parts by mass of the polymer (A) is preferably 0.1 parts by mass, more preferably 5 parts by mass, and still more preferably 15 parts by mass. The upper limit of the content is preferably 40 parts by mass, more preferably 30 parts by mass, and still more preferably 25 parts by mass. When the content of the acid generating agent (B) falls within the above range, sensitivity and developability of the radiation-sensitive resin composition of the embodiment of the present invention are improved, consequently enabling the LWR performance and CDU performance to be more improved. One, or two or more types of the acid generator (B) may be used.

In a case in which the polymer (A) has the structural unit represented by the above formula (7), the lower limit of the proportion of the structural unit contained with respect to the total structural units constituting the polymer (A) is preferably 0.5 mol %, and more preferably 3 mol %. Meanwhile, the upper limit of the proportion of the structural unit contained with respect to the total structural units constituting the polymer (A) is preferably 15 mol %, and more preferably 8 mol %. When the proportion of the structural unit contained falls within the above range, the radiation-sensitive resin composition is capable of leading to more improved LWR performance and CDU performance.

### (C) Solvent

The solvent (C) contained in the radiation-sensitive resin composition of the embodiment of the present invention is not particularly limited as long as the solvent (C) is capable of dissolving or dispersing at least the polymer (A) and the acid generator (B), as well as optional component(s) that may be contained as needed, and is exemplified by an alcohol solvent, an ether solvent, a ketone solvent, an amide solvent, an ester solvent, a hydrocarbon solvent, and the like. The radiation-sensitive resin composition may contain one, or two or more types of the solvent (C).

Examples of the alcohol solvent include:

aliphatic monohydric alcohol solvents having 1 to 18 carbon atoms such as 4-methyl-2-pentanol and n-hexanol;

alicyclic monohydric alcohol solvents having 3 to 18 carbon atoms such as cyclohexanol;

polyhydric alcohol solvents having 2 to 18 carbon atoms such as 1,2-propylene glycol;

polyhydric alcohol partial ether solvents having 3 to 19 carbon atoms such as propylene glycol monomethyl ether; and the like.

Examples of the ether solvent include:

dialkyl ether solvents such as diethyl ether, dipropyl ether, dibutyl ether, dipentyl ether, diisoamyl ether, dihexyl ether and diheptyl ether;

cyclic ether solvents such as tetrahydrofuran and tetrahydropyran;

aromatic ring-containing ether solvents such as diphenyl ether and anisole; and the like.

Examples of the ketone solvent include:

chain ketone solvents such as acetone, methyl ethyl ketone, methyl n-propyl ketone, methyl n-butyl ketone, diethyl ketone, methyl i-butyl ketone, 2-heptanone, ethyl n-butyl ketone, methyl n-hexyl ketone, methyl n-amyl ketone, di-i-butyl ketone and trimethylnonanone;

cyclic ketone solvents such as cyclopentanone, cyclohexanone, cycloheptanone, cyclooctanone and methylcyclohexanone;

2,4-pentanedione, acetonylacetone and acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methylacetamide, N,N-dimethylacetamide and N-methylpropionamide; and the like.

Examples of the ester solvent include:

monocarboxylic acid ester solvents such as i-propyl acetate, n-butyl acetate, amyl acetate and ethyl lactate;

polyhydric alcohol carboxylate solvents such as propylene glycol diacetate;

polyhydric alcohol partial ether carboxylate solvents such as propylene glycol monomethyl ether acetate;

polyhydric carboxylic acid diester solvents such as diethyl oxalate;

carbonate solvents such as dimethyl carbonate and diethyl carbonate; and the like.

Examples of the hydrocarbon solvent include:

aliphatic hydrocarbon solvents having 5 to 12 carbon atoms such as n-pentane and n-hexane;

aromatic hydrocarbon solvents having 6 to 16 carbon atoms such as toluene and xylene; and the like.

Of these, as the solvent (C), the ketone solvents, the ester solvents and mixed solvents of these are preferred, the cyclic ketone solvents, the polyhydric alcohol partial ether carboxylate solvents and mixed solvents of these are more preferred, and cyclohexanone, propylene glycol monomethyl ether acetate and a mixed solvent of these are still more preferred.

### (D) Acid Diffusion Controller

The acid diffusion controller (D) achieves the effect of controlling a diffusion phenomenon of the acid generated from the acid generator (D) upon an exposure in the resist film, and inhibiting unfavorable chemical reactions at light-unexposed regions. In addition, the storage stability of the radiation-sensitive resin composition is improved due to containing the acid diffusion controller (D). Furthermore, due to containing the acid diffusion controller (D), the radiation-sensitive resin composition of the embodiment of the present invention results in an improved resolution of the resist pattern, and variation of the line width of the resist pattern caused by variation of post exposure time delay from the exposure until a development treatment is inhibited, whereby the process stability may be improved. The acid diffusion controller (D) may be contained in the radiation-sensitive resin composition in the form of a free compound (hereinafter, may be also referred to as “(D) acid diffusion control agent” or “acid diffusion control agent (D)”), or in the form incorporated as a part of the polymer, or in both of these forms. The radiation-sensitive resin composition may contain one, or two or more types of the acid diffusion controller (D).

The acid diffusion control agent (D) is exemplified by a compound represented by the following formula (c-1) (hereinafter, may be also referred to as “nitrogen-containing compound (I)”), a compound having two nitrogen atoms in a single molecule (hereinafter, may be also referred to as “nitrogen-containing compound (II)”), a compound having three nitrogen atoms (hereinafter, may be also referred to as “nitrogen-containing compound (III)”), an amide group-containing compound, a urea compound, a nitrogen-containing heterocyclic compound, and the like.

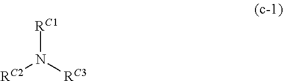

In the above formula (c-1), R^{C1}, R^{C2} and R^{C3} each independently represent a hydrogen atom, an unsubstituted or substituted linear, branched or cyclic alkyl group, an unsubstituted or substituted aryl group or an unsubstituted or substituted aralkyl group.

Examples of the nitrogen-containing compound (I) include: monoalkylamines such as n-hexylamine; dialkylamines such as di-n-butylamine; trialkylamines such as triethylamine; aromatic amines such as aniline; and the like.

Examples of the nitrogen-containing compound (II) include ethylenediamine, N,N,N′,N′-tetramethylethylenediamine, and the like.

Examples of the nitrogen-containing compound (III) include: polyamine compounds such as polyethyleneimine and polyallylamine; polymers of dimethylaminoethylacrylamide, etc.; and the like.

Examples of the amide group-containing compound include formamide, N-methylformamide, N,N-dimethylformamide, acetamide, N-methylacetamide, N,N-dimethylacetamide, propionamide, benzamide, pyrrolidone, N-methylpyrrolidone, and the like.

Examples of the urea compound include urea, methylurea, 1,1-dimethylurea, 1,3-dimethylurea, 1,1,3,3-tetramethylurea, 1,3-diphenylurea, tributylthiourea, and the like.

Examples of the nitrogen-containing heterocyclic compound include pyridines such as pyridine and 2-methylpyridine, pyrazine, pyrazole, and the like.

Alternatively, a compound having an acid-labile group may also be used as the acid diffusion control agent. Examples of the acid diffusion control agent having an acid-labile group include N-(t-butoxycarbonyl)piperidine, N-(t-butoxycarbonyl)imidazole, N-(t-butoxycarbonyl)benzimidazole, N-(t-butoxycarbonyl)-2-phenylbenzimidazole, N-(t-butoxycarbonyl)di-n-octylamine, N-(t-butoxycarbonyl)diethanolamine, N-(t-butoxycarbonyl)dicyclohexylamine, N-(t-butoxycarbonyl)diphenylamine, N-(t-butoxycarbonyl)-4-hydroxypiperidine, and the like.

A photolabile base which is sensitized upon an exposure to generate a weak acid may also be used as the acid diffusion controller (D). The photolabile base is exemplified by an onium salt compound that loses acid diffusion controllability through degradation upon an exposure, and the like. The onium salt compound is exemplified by a sulfonium salt compound represented by the following formula (c-2), an iodonium salt compound represented by the following formula (c-3), and the like.

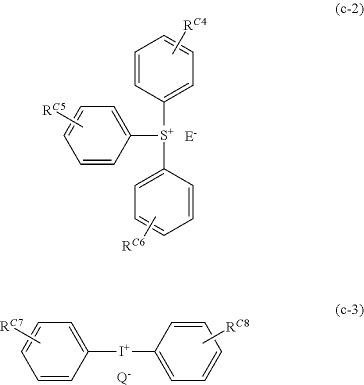

In the above formulae (c-2) and (c-3), R^{C4} to R^{C8} each independently represent a hydrogen atom, an alkyl group, an alkoxy group, a hydroxy group or a halogen atom; E⁻ and Q⁻ each independently represent OH—, R^{CC1}—COO⁻, R^{CC1}—SO₃⁻ or an anion represented by the following formula (c-4), wherein R^{CC1} represents an alkyl group, an aryl group or an aralkyl group.

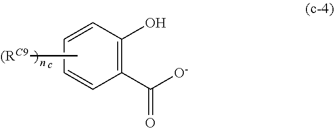

In the above formula (c-4), R^{C9} represents a linear or branched alkyl group having 1 to 12 carbon atoms, or a linear or branched alkoxyl group having 1 to 12 carbon atoms, wherein a part or all of hydrogen atoms included in the linear or branched alkyl group or the linear or branched alkoxyl group may be substituted with a fluorine atom; and n, is an integer of 0 to 2.

In a case in which the radiation-sensitive resin composition contains the acid diffusion control agent (D), the lower limit of the content of the acid diffusion control agent (D) with respect to 100 parts by mass of the polymer (A) is preferably 0.1 parts by mass, more preferably 1 part by mass, and still more preferably 3 parts by mass. Meanwhile, the upper limit of the content is preferably 20 parts by mass, more preferably 10 parts by mass, and still more preferably 7 parts by mass.

### Other Optional Component

The radiation-sensitive resin composition of the embodiment of the present invention may contain as other optional component, a fluorine atom-containing polymer having a greater percentage content of fluorine atoms than the polymer (A), as well as a localization accelerator, an alicyclic skeleton compound, a surfactant, a sensitizing agent, and the like.

Fluorine Atom-Containing Polymer

The fluorine atom-containing polymer has a percentage content of fluorine atoms (% by mass) that is greater than that of the polymer (A). In the case of the radiation-sensitive resin composition of the embodiment of the present invention containing the fluorine atom-containing polymer, when a resist film is formed, the fluorine atom-containing polymer tends to be localized in the surface region of the resist film due to oil repellent characteristics of the fluorine atom-containing polymer in the resist film, and consequently the elution of the acid generating agent, the acid diffusion control agent, etc., into a liquid immersion medium may be inhibited in the liquid immersion lithography and the like. In addition, due to water repellent characteristics of the fluorine atom-containing polymer, an advancing contact angle of a liquid immersion medium on the resist film can be controlled to fall within a desired range, thereby enabling inhibition of generation of bubble defects. Furthermore, a greater receding contact angle of the liquid immersion medium on the resist film is attained, whereby an exposure by high speed scanning without being accompanied by residual water beads is enabled. Thus, when the radiation-sensitive resin composition further contains the fluorine atom-containing polymer, a resist film suitable for liquid immersion lithography processes can be provided.

Localization Accelerator

The localization accelerator achieves the effect that for example, in the case of the radiation-sensitive resin composition of the embodiment of the present invention containing the fluorine atom-containing polymer, the fluorine atom-containing polymer is more efficiently localized in the surface region of the resist film. When the radiation-sensitive resin composition contains the localization accelerator, the amount of the fluorine atom-containing polymer added can be decreased than ever before. Therefore, elution of the component(s) from the resist film into a liquid immersion liquid is further inhibited, and quicker liquid immersion lithography is enabled by high speed scanning, without impairing the LWR performance and CDU performance of the radiation-sensitive resin composition. As a result, defects caused by the liquid immersion such as watermark defects can be efficiently inhibited. The localization accelerator is exemplified by a low molecular weight compound having a relative permittivity of no less than 30 and no greater than 200, and having a boiling point at 1 atmospheric pressure of no less than 100° C. Specific examples of such a compound include a lactone compound, a carbonate compound, a nitrile compound, a polyhydric alcohol, and the like.

### Preparation Method of Radiation-Sensitive Resin Composition

The radiation-sensitive resin composition of the embodiment of the present invention may be prepared, for example, by mixing the polymer (A), the acid generator (B), the solvent (C) and the optional component in a certain ratio. The radiation-sensitive resin composition thus prepared is preferably used after being filtered through a filter, etc., having a pore size of about 0.2 μm, for example. The lower limit of the solid content concentration of the resist composition is preferably 0.1% by mass, more preferably 0.5% by mass, and still more preferably 1.5% by mass. Meanwhile, the upper limit of the solid content concentration of the resist composition is preferably 50% by mass, more preferably 20% by mass, still more preferably 5% by mass, and particularly preferably 3% by mass.

### Resist Pattern-Forming Method

The resist pattern-forming method of the embodiment of the present invention includes the steps of applying the radiation-sensitive resin composition directly or indirectly on at least an upper face side of a substrate to form a resist film (hereinafter, may be also referred to as “applying step”), exposing the resist film (hereinafter, may be also referred to as “exposure step”), and developing the resist film exposed (hereinafter, may be also referred to as “development step”).

According to the resist pattern-forming method, since the radiation-sensitive resin composition of the embodiment of the present invention described above is used, a resist pattern that is superior in the LWR performance and the CDU performance can be formed. Hereinafter, each step will be described.

Applying Step

In this step, the radiation-sensitive resin composition of the embodiment of the present invention is applied directly or indirectly on at least an upper face side of a substrate to form a resist film. The substrate on which the radiation-sensitive resin composition is applied is exemplified by a conventionally well-known substrate such as a silicon wafer, a wafer coated with silicon dioxide or aluminum, and the like. Additionally, in this step, an organic or inorganic antireflective film disclosed in, for example, Japanese Examined Patent Application, Publication No. H6-12452, Japanese Unexamined Patent Application, Publication No. S59-93448, or the like may be formed on the substrate, and then the radiation-sensitive resin composition may be applied on the antireflective film.

An application procedure of the radiation-sensitive resin composition is exemplified by spin-coating, cast coating, roll-coating, and the like. After the application, prebaking (PB) may be carried out as needed for evaporating the solvent remaining in the coating film. The lower limit of the PB temperature is preferably 60° C., and more preferably 80° C. Meanwhile, the upper limit of the PB temperature is preferably 140° C., and more preferably 120° C. The lower limit of the time period for PB is preferably 5 sec, and more preferably 10 sec. Meanwhile, the upper limit of the time period for PB is preferably 600 sec, and more preferably 300 sec. The lower limit of the average thickness of the resist film formed is preferably 10 nm. The upper limit of the average thickness of the resist film formed is preferably 1,000 nm, and more preferably 500 nm.

Exposure Step

In this step, the resist film obtained in the applying step is exposed by irradiating the resist film with exposure light through a photomask or the like. Examples of the exposure light include: electromagnetic waves such as visible light rays, ultraviolet rays, far ultraviolet rays, extreme ultraviolet rays (EUV), X-rays, and γ-rays; charged particle rays such as electron beams and α-rays; and the like, in accordance with the line width of the intended pattern. Of these, the exposure light is preferably the far ultraviolet rays, more preferably an ArF excimer laser beam (wavelength: 193 nm) or a KrF excimer laser beam (wavelength: 248 nm), and still more preferably an ArF excimer laser beam.

The exposure may be conducted through a liquid immersion medium. In other words, the exposure may be carried out by liquid immersion lithography. The liquid immersion medium is exemplified by water, a fluorine-containing inert liquid and the like. It is preferred that the liquid immersion medium is transparent to an exposure wavelength, and has a temperature coefficient of the refractive index as small as possible, in light of possible minimization of distortion of an optical image projected onto the film. In particular, when an ArF excimer laser beam (wavelength: 193 nm) is used as an exposure light source, the liquid immersion medium is preferably water in light of availability and ease of handling thereof in addition to the aforementioned viewpoints. The water for use as the liquid immersion medium is preferably distilled water. When water is used as the liquid immersion medium, a slight amount of an additive which reduces the surface tension of water and imparts enhanced interfacial activity may be added. It is preferred that the additive hardly dissolves a resist film on a wafer and has a negligible influence on an optical coating of an inferior face of a lens.

When water is used as the liquid immersion medium, the lower limit of the receding contact angle of the water on the surface of the formed resist film is preferably 75°, more preferably 78°, still more preferably 81°, particularly preferably 850, and further particularly preferably 90°. Meanwhile, the upper limit of the receding contact angle is typically 100°. When the receding contact angle falls within the above range, carrying out higher speed scanning is enabled in the liquid immersion lithography.

It is preferred that post exposure baking (PEB) is carried out after the exposure to promote dissociation of the acid-labile group included in the polymer (A), etc., mediated by the acid generated from the acid generator (B) upon the exposure at exposed regions of the resist film. This PEB enables a difference to be increased in solubility of the resist film in a developer solution between the light-exposed regions and the light-unexposed regions. The lower limit of the temperature for PEB is preferably 50° C., and more preferably 80° C. Meanwhile, the upper limit of the temperature for PEB is preferably 180° C., and more preferably 130° C. The lower limit of the time period for PEB is preferably 5 sec, and more preferably 10 sec. Meanwhile, the upper limit of the time period for PEB is preferably 600 sec, and more preferably 300 sec.

Development Step

In this step, the resist film exposed in the exposure step is developed by using a developer solution. Accordingly, a predetermined resist pattern is formed. The developer solution is exemplified by an alkaline aqueous solution, a developer solution containing an organic solvent as a principal component, and the like. When the alkaline aqueous solution is used as the developer solution, a positive-tone pattern can be obtained. Meanwhile, when the developer solution containing an organic solvent as a principal component is used as the developer solution, a negative tone pattern can be obtained. The term “principal component” as referred to herein means a component which is of the highest content, for example, a component the content of which is no less than 50% by mass.

Examples of the alkaline aqueous solution include alkaline aqueous solutions prepared by dissolving at least one alkaline compound such as sodium hydroxide, potassium hydroxide, sodium carbonate, sodium silicate, sodium metasilicate, ammonia water, ethylamine, n-propylamine, diethyl amine, di-n-propylamine, triethylamine, methyldiethyl amine, ethyldimethyl amine, triethanolamine, tetramethylammonium hydroxide (TMAH), pyrrole, piperidine, choline, 1,8-diazabicyclo-[5.4.0]-7-undecene, 1,5-diazabicyclo-[4.3.0]-5-nonene, and the like.

The lower limit of the content of the alkaline compound in the alkaline aqueous solution is preferably 0.1% by mass, more preferably 0.5% by mass, and still more preferably 1% by mass. The upper limit of the content is preferably 20% by mass, more preferably 10% by mass, and still more preferably 5% by mass.

The alkaline aqueous solution is preferably an aqueous TMAH solution, and more preferably a 2.38% by mass aqueous TMAH solution.

Examples of the organic solvent which may be used in the developer solution containing the organic solvent as a principal component include the solvents exemplified in connection with the solvent (C) of the abovementioned radiation-sensitive resin composition of the embodiment of the present invention, and the like. Of these, the ester solvent is preferred, and butyl acetate is more preferred. These organic solvents may be used either alone of one type, or as a mixture of two or more types thereof.

The lower limit of the content of the organic solvent in the developer solution containing the organic solvent as a principal component is preferably 80% by mass, more preferably 90% by mass, still more preferably 95% by mass, and particularly preferably 99% by mass. When the content of the organic solvent falls within the above range, contrast between the light-exposed regions and the light-unexposed regions can be improved. It is to be noted that a component other than the organic solvent in the developer solution containing the organic solvent as a principal component is exemplified by water, silicone oil, and the like.

In this step, the developer solution containing the organic solvent as a principal component is preferably used. Since adequately adjusted dissolution contrast between the light-exposed regions and the light-unexposed regions is enabled in the resist film formed from the radiation-sensitive resin composition of the embodiment of the present invention, the resist film can be suitably used in the development with the developer solution containing the organic solvent as a principal component.

As needed, a surfactant may be added in an appropriate amount to the developer solution. As the surfactant, for example, an ionic or nonionic fluorochemical surfactant, and/or a silicone-based surfactant may be used.

Examples of the development procedure include: a dipping method in which the substrate is immersed for a given time period in the developer solution charged in a bath; a puddle method in which the developer solution is placed to form a dome-shaped bead by way of the surface tension on the surface of the substrate for a given time period to conduct a development; a spraying method in which the developer solution is sprayed onto the surface of the substrate; a dynamic dispensing method in which the developer solution is continuously applied onto the substrate that is rotated at a constant speed while scanning with a developer solution-application nozzle at a constant speed; and the like.

It is preferred that the substrate after being subjected to the development is rinsed with a rinse agent such as water or an alcohol and thereafter dried. Examples of the rinse procedure include: a spin-coating method in which the rinse agent is continuously applied onto the substrate that is rotated at a constant speed; a dip coating method in which the substrate is immersed for a given time period in the rinse agent charged in a bath; a spray coating method in which the rinse agent is sprayed onto the surface of the substrate; and the like.

### EXAMPLES

Hereinafter, the embodiments of the present invention will be explained in detail by way of Examples, but the present invention is not in any way limited to these Examples. Physical property values in Examples were measured as in the following.

Weight Average Molecular Weight (Mw) and Number Average Molecular Weight (Mn)

Mw and Mn of the polymer were determined by gel permeation chromatography (GPC) by using GPC columns available from Tosoh Corporation (“G2000 HXL”×2, “G3000 HXL”×1 and “G4000 HXL”×1), a differential refractometer as a detector, and mono-dispersed polystyrene as a standard under analytical conditions involving a flow rate of 1.0 mL/min, an elution solvent of tetrahydrofuran, a sample concentration of 1.0% by mass, an amount of injected sample of 100 μL, and a column temperature of 40° C. Moreover, the dispersity index (Mw/Mn) was calculated based on the results of the determination of the Mw and the Mn.

¹³C-NMR Analysis

A ¹³C-NMR analysis for determining the proportions of structural units contained in each polymer was carried out by using a nuclear magnetic resonance apparatus (“JNM-ECX400” available from JEOL, Ltd.) and deuterochloroform as a solvent for measurement.

### Syntheses of Compounds (i)

### Synthesis Example 1: Synthesis of Compound (i-1)

Into a nitrogen-substituted three-neck flask, 11.6 g of diacetone alcohol (100 mmol), 100 mL of methylene chloride and 11.1 g of triethylamine (110 mmol) were charged and then cooled to 0° C. Thereafter, a solution prepared by dissolving 11.0 g of methacryloyl chloride (105 mmol) in 100 mL of tetrahydrofuran was added dropwise into the three-neck flask. After completion of the dropwise addition, a reaction solution thus obtained was stirred at room temperature for 3 hrs, and then 200 mL of ultra pure water was added thereto to quench the reaction. Next, 300 mL of ethyl acetate was added to the reaction solution to permit liquid separation, and the underlayer was extracted twice with 100 mL of ethyl acetate. Thereafter, the organic layer was washed with 200 mL of ultra pure water, 200 mL of a saturated aqueous sodium bicarbonate solution, and 200 mL of a saturated saline solution, followed by dehydration over magnesium sulfate. To the dehydrated solution was added a small amount of phenothiazine as a polymerization inhibitor, and then the solvent was distilled off. The liquid obtained by distillation of the solvent was thereafter distilled off under reduced pressure to give 13.1 g of an intended compound (i-1) represented by the following formula (i-1) as a colorless transparent liquid.

### Synthesis Example 2: Synthesis of Compound (i-2)

Into a nitrogen-substituted three-neck flask, 100 mL of tetrahydrofuran and 68.8 mL of lithium diisopropylamide (1.6 M hexane solution) were charged and then cooled to −78° C. Next, a solution prepared by dissolving 5.8 g of acetone (100 mmol) in 100 mL of tetrahydrofuran was added dropwise into the three-neck flask. After the reaction solution obtained by the dropwise addition was stirred at −78° C. for 1 hr, a solution prepared by dissolving 8.4 g of cyclopentanone (100 mmol) in 50 mL of tetrahydrofuran was added dropwise to the reaction solution. After completion of the dropwise addition, the reaction solution was stirred at room temperature for 2 hrs, and then 10 mL of ultra pure water and 200 mL of a saturated aqueous ammonium chloride solution were further added thereto to quench the reaction. Next, 200 mL of ethyl acetate was added to the reaction solution to permit liquid separation, and the aqueous layer was extracted twice with 100 mL of ethyl acetate. Thereafter, the organic layer was washed with 100 mL of ultra pure water and 100 mL of a saturated aqueous sodium chloride solution, followed by drying over magnesium sulfate. The solvent was distilled off from the solution after drying, and purified by silica gel column chromatography to give 9.7 g of 1-(1-hydroxycyclopentyl)ethanone. Next, this 1-(1-hydroxycyclopentyl)ethanone was subjected to methacrylate esterification by a procedure similar to that in Synthesis Example 1 described above to give 9.7 g of an intended compound (i-2) represented by the following formula (i-2).

### Synthesis Examples 3 to 7: Syntheses of Compounds (i-3) to (i-7)

Compounds (i-3) to (i-7) represented by the following formulae (i-3) to (i-7) were synthesized by carrying out similar operations to those in Synthesis Example 2 by using each appropriate ketone.

### Synthesis Example 8: Synthesis of Compound (i-8)

Into a nitrogen-substituted three-neck flask, 8.7 g of pyridine (110 mmol), 17.8 g of 1,1′-carbonyldiimidazole (110 mmol), 14.8 g of 4-vinylbenzoic acid (100 mmol), and 200 mL of dimethylformamide were charged, and the mixture was stirred at room temperature for 12 hrs. Thereafter, 200 mL of ultra pure water and 300 mL of ethyl acetate were added to the solution in the three-neck flask, and liquid separation was carried out. Next, the organic layer obtained after the liquid separation was washed with 100 mL of a saturated aqueous sodium carbonate solution, 100 mL of ultra pure water and 100 mL of a saturated saline solution, and dried over magnesium sulfate. The solvent was distilled off from the solution after drying to give 22.6 g an intended compound (i-8) represented by the following formula (i-8).

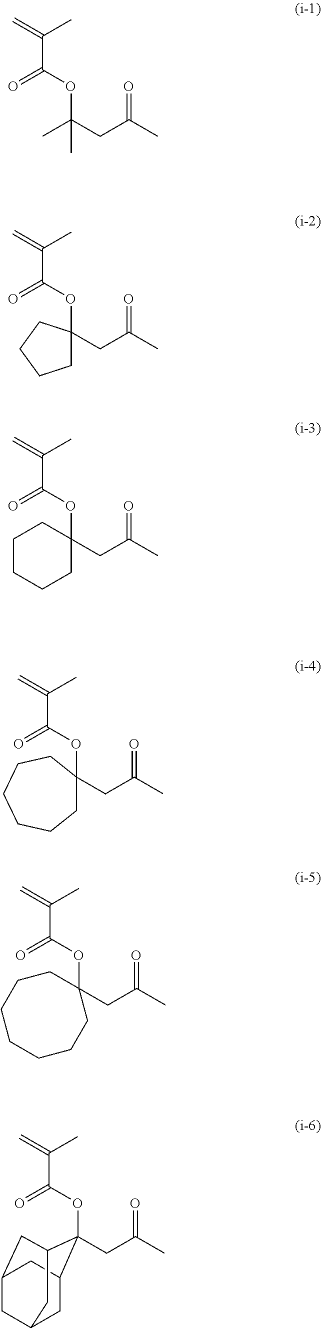

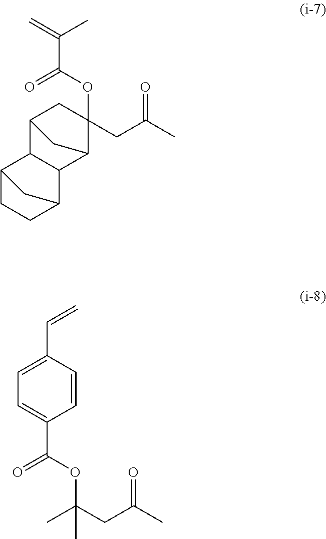 [SMILES: C=C(C)C(=O)OC1(CC(C)=O)CC2CC1C1C3CCC(C3)C21 ; C=Cc1ccc(C(=O)OC(C)(C)CC(C)=O)cc1]

### Syntheses of Polymers (A)

Monomers other than the compounds (i-1) to (i-8) used for syntheses of polymers (A) are shown by the following formulae.

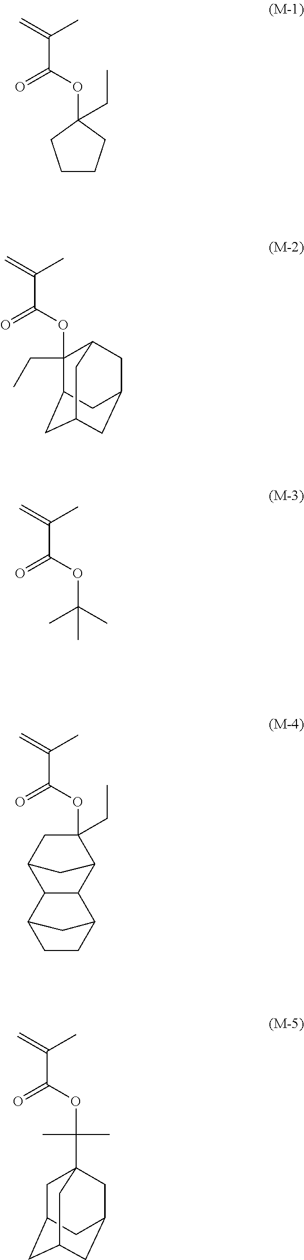

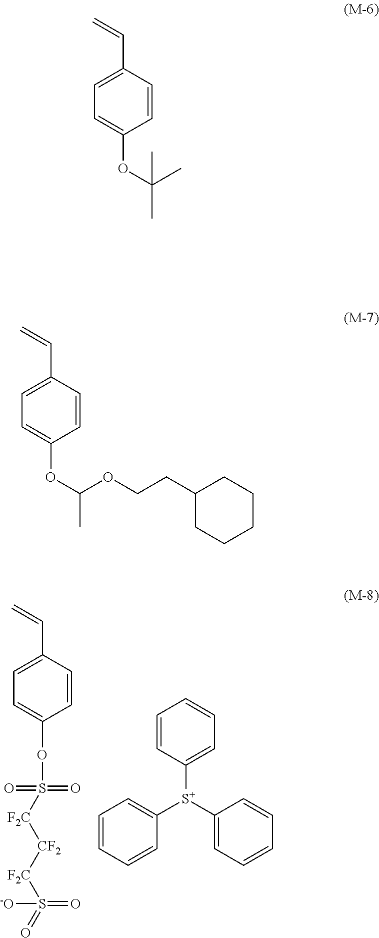

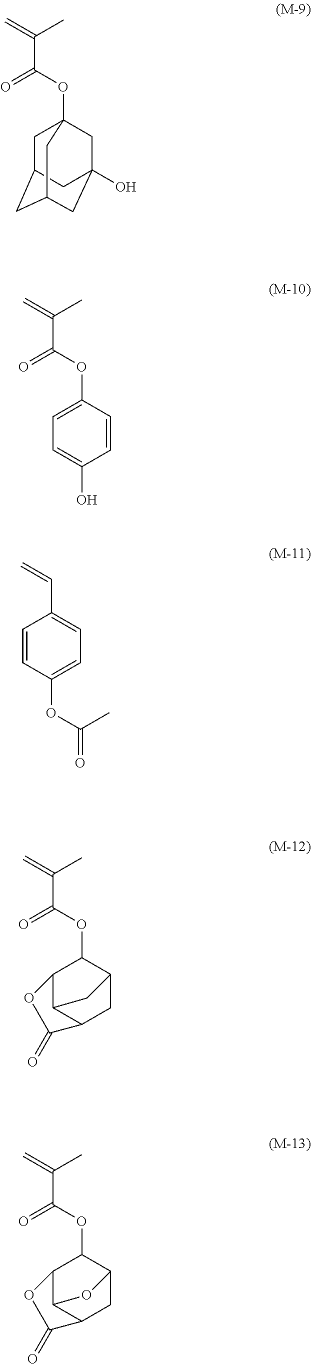 [SMILES: C=C(C)C(=O)OC12CC3CC(CC(O)(C3)C1)C2 ; C=C(C)C(=O)Oc1ccc(O)cc1 ; C=Cc1ccc(OC(C)=O)cc1 ; C=C(C)C(=O)OC1C2CC3C(=O)OC1C3C2 ; C=C(C)C(=O)OC1C2CC3C(=O)OC1C3O2]

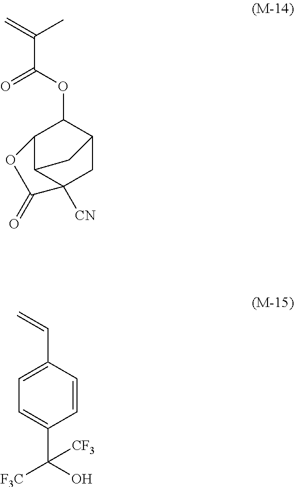 [SMILES: C=C(C)C(=O)OC1C2CC3C1OC(=O)C3(C#N)C2 ; C=Cc1ccc(C(O)(C(F)(F)F)C(F)(F)F)cc1]

### Synthesis Example 9: Synthesis of Polymer (A-1)

A monomer solution was prepared by: providing 21.01 g in total of the compound (M-1), the compound (M-12) and the compound (i-1) as monomers to give a molar ratio of 50/45/5; dissolving the same in 40 g of 2-butanone; and further adding to this solution AIBN as an initiator (5 mol % with respect to the total number of moles). Next, a three-neck flask containing 20 g of 2-butanone was purged with nitrogen for 30 min, then heated to 80° C. with stirring, and the monomer solution prepared as described above was added dropwise over 3 hrs using a dropping funnel into this three-neck flask. The time point of the start of the dropwise addition was regarded as the time of the start of the polymerization reaction, and the polymerization reaction was allowed to proceed for 6 hrs. After the completion of the polymerization reaction, the polymerization solution was water-cooled to 30° C. or below. The cooled polymerization solution was poured into 400 g of methanol, and a precipitated white powder was filtered off. The collected white powder was washed twice with 80 g of methanol, followed by separation by further filtration, and thereafter dried at 50° C. for 17 hrs to give 14.2 g of a polymer (A-1) as a white powder. The polymer (A-1) had Mw of 6,800 and an Mw/Mn of 1.55. The result of ¹³C-NMR analysis indicated that the proportions of the structural units derived from the compound (M-1), the compound (M-12) and the compound (i-1) were 49.3 mol %, 45.6 mol % and 5.1 mol %, respectively.

Synthesis Examples 10 to 25, 27 to 42 and 44 to 48: Syntheses of Polymers (A-2) to (A-17), (A-19) to (A-34) and (A-36) to (A-40)

Polymers (A-2) to (A-17), (A-19) to (A-34) and (A-36) to (A-40) were synthesized by using a similar procedure to that of Synthesis Example 9 described above except that the type and the amount of the monomers used were as shown in Table 1.

### Synthesis Example 26: Synthesis of Polymer (A-18)

A monomer solution was prepared by: providing 20 g in total of the compound (M-1), the compound (i-1) and the compound (M-11) as monomers to give a molar ratio of 55/5/40; dissolving the same in 40 g of propylene glycol monomethyl ether; and further adding to this solution AIBN as an initiator (5 mol % with respect to the total number of moles). Next, a 100 mL three-neck flask containing 20 g of propylene glycol monomethyl ether was purged with nitrogen for 30 min, then heated to 80° C. with stirring, and the monomer solution prepared as described above was added dropwise over 3 hrs using a dropping funnel into this three-neck flask. The time point of the start of the dropwise addition was regarded as the time of the start of the polymerization reaction, and the polymerization reaction was allowed to proceed for 6 hrs. After the completion of the polymerization reaction, the polymerization solution was water-cooled to 30° C. or below. The cooled polymerization solution was poured into 400 g of hexane, and a precipitated white powder was filtered off. The collected white powder was washed twice with 80 g of hexane, followed by separation by further filtration, and then dried at 50° C. for 17 hrs. Thereafter, the white powder was charged into a 100 mL eggplant-shaped flask and was dissolved in 40 g of propylene glycol monomethyl ether. Furthermore, 5.1 g of triethylamine and 0.91 g of pure water were added to this solution, and the mixture was heated to 80° C., thereby allowing for hydrolysis through a reaction for 6 hrs. After completion of the hydrolysis, the reaction liquid was water-cooled to 30° C. or below. The reaction liquid cooled was placed into 400 g of hexane, and thus precipitated white powder was filtered off. After the collected white powder was washed with 80 g of hexane twice, further filtration and drying at 50° C. for 17 hrs gave 14.2 g of a polymer (A-18).

### Synthesis Example 41: Synthesis of Polymer (A-35)

A polymer (A-35) was synthesized by using a similar procedure to that of Synthesis Example 26 described above except that the type and the amount of the monomers used were as shown in Table 1.

Table 1 shows the yield (%), Mw, Mw/Mn ratio, proportion of each structural unit contained (mol %) of the polymers synthesized as described above. The symbol “-” in Table 1 indicates that the corresponding monomer was not used.

TABLE 1

| | Structural unit (I) | | | Structural unit (II) | | | Structural unit (III) | | | Other structural unit | | | | | |
|---|---|---|---|---|---|---|---|---|---|---|---|---|---|---|---|
| | | | proportion | | | proportion | | | proportion | | | proportion | | | |
| | | | of | | | of | | | of | | | of | | | |
| | | | structural | | | structural | | | structural | | | structural | | | |
| | | amount | unit | | amount | unit | | amount | unit | | amount | unit | Yield | | Mw/ |
| Polymer | type | (mol %) | (mol %) | type | (mol %) | (mol %) | type | (mol %) | (mol %) | type | (mol %) | (mol %) | (%) | Mw | Mn |
| A-1 | i-1 | 5 | 5.1 | M-1 | 50 | 49.3 | M-12 | 45 | 45.6 | — | — | — | 71 | 6,800 | 1.55 |
| A-2 | i-2 | 10 | 9.8 | M-1 | 45 | 44.8 | M-12 | 45 | 45.4 | — | — | — | 73 | 6,800 | 1.54 |
| A-3 | i-3 | 10 | 10.1 | M-1 | 45 | 44.9 | M-12 | 45 | 45.0 | — | — | — | 73 | 6,900 | 1.53 |
| A-4 | i-4 | 10 | 9.9 | M-1 | 45 | 45.0 | M-12 | 45 | 45.1 | — | — | — | 76 | 6,800 | 1.55 |
| A-5 | i-5 | 50 | 49.7 | M-1 | 5 | 5.2 | M-12 | 45 | 45.1 | — | — | — | 73 | 6,800 | 1.52 |
| A-6 | i-6 | 20 | 19.6 | M-1 | 25 | 25.3 | M-12 | 45 | 55.1 | — | — | — | 75 | 6,700 | 1.55 |
| A-7 | i-7 | 10 | 9.9 | M-1 | 45 | 44.9 | M-12 | 45 | 45.2 | — | — | — | 77 | 6,900 | 1.54 |
| A-8 | i-8 | 5 | 5.2 | M-1 | 50 | 50.3 | M-12 | 45 | 44.5 | — | — | — | 69 | 6,900 | 1.53 |
| A-9 | i-1 | 5 | 4.8 | M-2 | 50 | 50.3 | M-12 | 45 | 44.9 | — | — | — | 74 | 6,900 | 1.55 |
| A-10 | i-1 | 5 | 5.1 | M-3 | 50 | 49.9 | M-12 | 45 | 45.0 | — | — | — | 73 | 6,900 | 1.49 |
| A-11 | i-1 | 5 | 5.0 | M-4 | 50 | 50.2 | M-12 | 45 | 44.8 | — | — | — | 69 | 6,900 | 1.56 |
| A-12 | i-1 | 5 | 5.0 | M-5 | 50 | 49.7 | M-12 | 45 | 45.3 | — | — | — | 73 | 6,900 | 1.60 |
| A-13 | i-1 | 5 | 4.8 | M-6 | 50 | 49.8 | M-12 | 45 | 45.4 | — | — | — | 71 | 6,700 | 1.58 |
| A-14 | i-1 | 5 | 5.2 | M-7 | 50 | 49.7 | M-12 | 45 | 45.1 | — | — | — | 69 | 6,900 | 1.55 |
| A-15 | i-1 | 5 | 4.6 | M-1 | 50 | 50.1 | M-13 | 45 | 45.3 | — | — | — | 70 | 6,800 | 1.52 |
| A-16 | i-1 | 5 | 4.9 | M-1 | 50 | 49.6 | M-14 | 45 | 45.5 | — | — | — | 70 | 6,900 | 1.53 |
| A-17 | i-1 | 5 | 5.2 | M-1 | 50 | 50.3 | M-10 | 45 | 44.5 | — | — | — | 74 | 6,700 | 1.55 |
| A-18 | i-1 | 5 | 5.1 | M-1 | 55 | 54.4 | M-11 | 40 | 40.5 | — | — | — | 71 | 6,700 | 1.57 |
| A-19 | i-1 | 5 | 4.8 | M-1 | 50 | 50.0 | M-10 | 35 | 35.4 | M- | 10 | 9.8 | 72 | 6,600 | 1.56 |
| | | | | | | | | | | 15 | | | | | |
| A-20 | i-1 | 5 | 5.0 | M-1 | 50 | 49.2 | M-15 | 45 | 45.8 | — | — | — | 69 | 6,900 | 1.54 |
| A-21 | i-1 | 5 | 5.2 | M-1 | 50 | 50.1 | M-9 | 45 | 44.7 | — | — | — | 69 | 6,900 | 1.57 |
| A-22 | i-1 | 5 | 4.9 | M-1 | 50 | 49.9 | M-12 | 40 | 40.2 | M-8 | 5 | 5.0 | 70 | 7,000 | 1.54 |
| A-23 | i-1 | 10 | 9.9 | M-1 | 45 | 44.9 | M-12 | 45 | 45.2 | — | — | — | 68 | 6,900 | 1.55 |
| A-24 | i-1 | 20 | 19.8 | M-1 | 35 | 34.7 | M-12 | 45 | 45.5 | — | — | — | 68 | 6,900 | 1.55 |
| A-25 | — | — | — | M-1 | 55 | 55.2 | M-12 | 45 | 44.8 | — | — | — | 70 | 6,900 | 1.55 |
| A-26 | — | — | — | M-2 | 55 | 54.8 | M-12 | 45 | 45.2 | — | — | — | 73 | 6,900 | 1.55 |
| A-27 | — | — | — | M-3 | 55 | 54.9 | M-12 | 45 | 45.1 | — | — | — | 72 | 7,000 | 1.52 |
| A-28 | — | — | — | M-4 | 55 | 54.7 | M-12 | 45 | 45.3 | — | — | — | 72 | 6,900 | 1.57 |
| A-29 | — | — | — | M-5 | 55 | 55.3 | M-12 | 45 | 44.7 | — | — | — | 70 | 6,900 | 1.53 |
| A-30 | — | — | — | M-6 | 55 | 55.0 | M-12 | 45 | 45.0 | — | — | — | 71 | 6,900 | 1.54 |
| A-31 | — | — | — | M-7 | 55 | 55.3 | M-12 | 45 | 44.7 | — | — | — | 70 | 7,100 | 1.54 |
| A-32 | — | — | — | M-1 | 55 | 55.3 | M-13 | 45 | 44.7 | — | — | — | 69 | 6,900 | 1.55 |
| A-33 | — | — | — | M-1 | 55 | 55.2 | M-14 | 45 | 44.8 | — | — | — | 69 | 6,800 | 1.53 |
| A-34 | — | — | — | M-1 | 55 | 54.8 | M-10 | 45 | 45.2 | — | — | — | 72 | 6,900 | 1.57 |
| A-35 | — | — | — | M-1 | 60 | 59.9 | M-11 | 40 | 40.1 | — | — | — | 70 | 6,800 | 1.55 |
| A-36 | — | — | — | M-1 | 55 | 54.9 | M-10 | 35 | 35.1 | M- | 10 | 10.0 | 70 | 6,900 | 1.57 |
| | | | | | | | | | | 15 | | | | | |
| A-37 | — | — | — | M-1 | 55 | 55.1 | M-15 | 45 | 44.9 | — | — | — | 69 | 6,700 | 1.56 |
| A-38 | — | — | — | M-1 | 55 | 55.2 | M-9 | 45 | 44.8 | — | — | — | 70 | 6,700 | 1.56 |
| A-39 | — | — | — | M-1 | 55 | 55.1 | M-12 | 40 | 39.9 | M-8 | 5 | 5.0 | 69 | 7,000 | 1.55 |
| A-40 | i-1 | 55 | 54.8 | — | — | — | M-12 | 45 | 45.2 | — | — | — | 70 | 6,800 | 1.58 |

### Preparation of Radiation-Sensitive Resin Composition

The acid generating agent (B), the solvent (C) and the acid diffusion control agent (D) which were used in the preparation of radiation-sensitive resin compositions are shown below.

(B) Acid Generating Agent

B-1: triphenylsulfonium 2-(adamantan-1-ylcarbonyloxy)-1,1,3,3,3-pentafluoropropane-1-sulfonate (a compound represented by the following formula (B-1))

B-2: triphenylsulfonium nonafluoro-n-butane-1-sulfonate (a compound represented by the following formula (B-2))

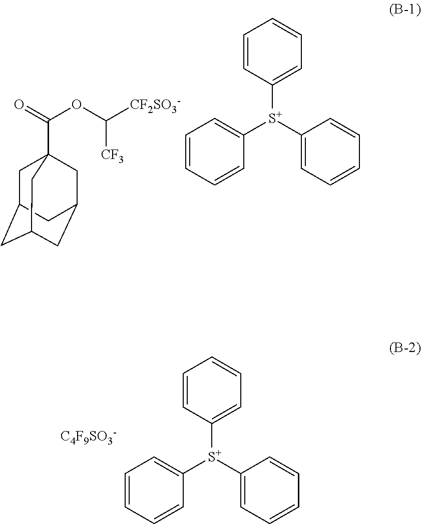

(C) Solvent

C-1: propylene glycol monomethyl ether acetate

C-2: cyclohexanone

(D) Acid Diffusion Control Agent

D-1: triphenylsulfonium 10-camphorsulfonate (a compound represented by the following formula (D-1))

D-2: triphenylsulfonium salicylate (a compound represented by the following formula (D-2))

D-3: tri-n-pentylamine (a compound represented by the following formula (D-3))

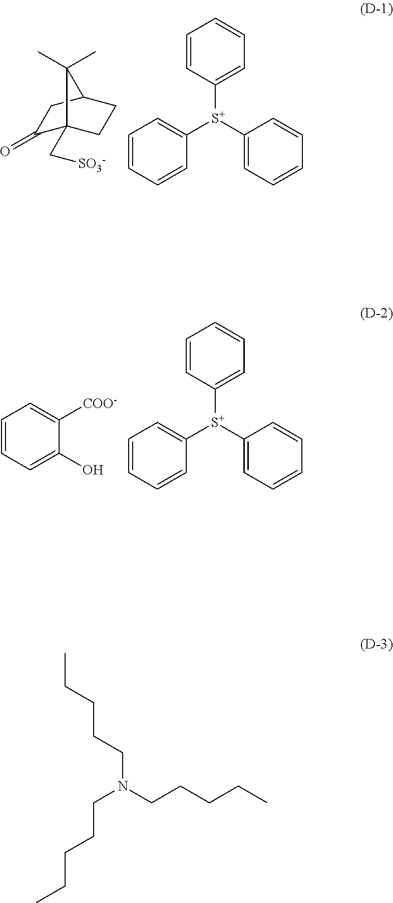

### Example 1

A radiation-sensitive resin composition (R-1) was prepared by blending: 100 parts by mass of (A-1) as the polymer (A); 20 parts by mass of (B-1) as the acid generating agent (B); 4,288 parts by mass of (C-1) and 1,837 parts by mass of (C-2) as the solvent (C), and 5 parts by mass of (D-1) as the acid diffusion control agent (D).

### Examples 2 to 27 and Comparative Examples 1 to 19

Radiation-sensitive resin compositions (R-2) to (R-27) and (CR-1) to (CR-19) were prepared by a similar operation to that of Example 1 except that the type and the content of each component used were as shown in Table 2.

TABLE 2

| | | | | (B) Acid | | | | (D) Acid | |
|---|---|---|---|---|---|---|---|---|---|
| | | (A) | | generating | | | | diffusion | |
| | Radiation- | Polymer | | agent | | (C) Solvent | | control agent | |
| | sensitive | | content | | content | | content | | content |
| | resin | | (parts by | | (parts by | | (parts by | | (parts by |
| | composition | type | mass) | type | mass) | type | mass) | type | mass) |
| Example 1 | R-1 | A-1 | 100 | B-1 | 20 | C-1/C-2 | 4288/1837 | D-1 | 5 |
| Example 2 | R-2 | A-2 | 100 | B-1 | 20 | C-1/C-2 | 4288/1837 | D-1 | 5 |
| Example 3 | R-3 | A-3 | 100 | B-1 | 20 | C-1/C-2 | 4288/1837 | D-1 | 5 |
| Example 4 | R-4 | A-4 | 100 | B-1 | 20 | C-1/C-2 | 4288/1837 | D-1 | 5 |
| Example 5 | R-5 | A-5 | 100 | B-1 | 20 | C-1/C-2 | 4288/1837 | D-1 | 5 |
| Example 6 | R-6 | A-6 | 100 | B-1 | 20 | C-1/C-2 | 4288/1837 | D-1 | 5 |
| Example 7 | R-7 | A-7 | 100 | B-1 | 20 | C-1/C-2 | 4288/1837 | D-1 | 5 |
| Example 8 | R-8 | A-8 | 100 | B-1 | 20 | C-1/C-2 | 4288/1837 | D-1 | 5 |
| Example 9 | R-9 | A-9 | 100 | B-1 | 20 | C-1/C-2 | 4288/1837 | D-1 | 5 |
| Example 10 | R-10 | A-10 | 100 | B-1 | 20 | C-1/C-2 | 4288/1837 | D-1 | 5 |
| Example 11 | R-11 | A-11 | 100 | B-1 | 20 | C-1/C-2 | 4288/1837 | D-1 | 5 |
| Example 12 | R-12 | A-12 | 100 | B-1 | 20 | C-1/C-2 | 4288/1837 | D-1 | 5 |
| Example 13 | R-13 | A-13 | 100 | B-1 | 20 | C-1/C-2 | 4288/1837 | D-1 | 5 |
| Example 14 | R-14 | A-14 | 100 | B-1 | 20 | C-1/C-2 | 4288/1837 | D-1 | 5 |
| Example 15 | R-15 | A-15 | 100 | B-1 | 20 | C-1/C-2 | 4288/1837 | D-1 | 5 |
| Example 16 | R-16 | A-16 | 100 | B-1 | 20 | C-1/C-2 | 4288/1837 | D-1 | 5 |
| Example 17 | R-17 | A-17 | 100 | B-1 | 20 | C-1/C-2 | 4288/1837 | D-1 | 5 |
| Example 18 | R-18 | A-18 | 100 | B-1 | 20 | C-1/C-2 | 4288/1837 | D-1 | 5 |
| Example 19 | R-19 | A-19 | 100 | B-1 | 20 | C-1/C-2 | 4288/1837 | D-1 | 5 |
| Example 20 | R-20 | A-20 | 100 | B-1 | 20 | C-1/C-2 | 4288/1837 | D-1 | 5 |
| Example 21 | R-21 | A-21 | 100 | B-1 | 20 | C-1/C-2 | 4288/1837 | D-1 | 5 |
| Example 22 | R-22 | A-22 | 100 | — | — | C-1/C-2 | 4288/1837 | D-1 | 5 |
| Example 23 | R-23 | A-1 | 100 | B-2 | 20 | C-1/C-2 | 4288/1837 | D-1 | 5 |
| Example 24 | R-24 | A-1 | 100 | B-1 | 20 | C-1/C-2 | 4288/1837 | D-2 | 5 |
| Example 25 | R-25 | A-1 | 100 | B-1 | 20 | C-1/C-2 | 4288/1837 | D-3 | 5 |
| Example 26 | R-26 | A-23 | 100 | B-1 | 20 | C-1/C-2 | 4288/1837 | D-1 | 5 |
| Example 27 | R-27 | A-24 | 100 | B-1 | 20 | C-1/C-2 | 4288/1837 | D-1 | 5 |
| Comparative | CR-1 | A-25 | 100 | B-1 | 20 | C-1/C-2 | 4288/1837 | D-1 | 5 |
| Example 1 | | | | | | | | | |
| Comparative | CR-2 | A-26 | 100 | B-1 | 20 | C-1/C-2 | 4288/1837 | D-1 | 5 |
| Example 2 | | | | | | | | | |
| Comparative | CR-3 | A-27 | 100 | B-1 | 20 | C-1/C-2 | 4288/1837 | D-1 | 5 |
| Example 3 | | | | | | | | | |
| Comparative | CR-4 | A-28 | 100 | B-1 | 20 | C-1/C-2 | 4288/1837 | D-1 | 5 |
| Example 4 | | | | | | | | | |
| Comparative | CR-5 | A-29 | 100 | B-1 | 20 | C-1/C-2 | 4288/1837 | D-1 | 5 |
| Example 5 | | | | | | | | | |
| Comparative | CR-6 | A-30 | 100 | B-1 | 20 | C-1/C-2 | 4288/1837 | D-1 | 5 |
| Example 6 | | | | | | | | | |
| Comparative | CR-7 | A-31 | 100 | B-1 | 20 | C-1/C-2 | 4288/1837 | D-1 | 5 |
| Example 7 | | | | | | | | | |
| Comparative | CR-8 | A-32 | 100 | B-1 | 20 | C-1/C-2 | 4288/1837 | D-1 | 5 |
| Example 8 | | | | | | | | | |
| Comparative | CR-9 | A-33 | 100 | B-1 | 20 | C-1/C-2 | 4288/1837 | D-1 | 5 |
| Example 9 | | | | | | | | | |
| Comparative | CR-10 | A-34 | 100 | B-1 | 20 | C-1/C-2 | 4288/1837 | D-1 | 5 |
| Example 10 | | | | | | | | | |
| Comparative | CR-11 | A-35 | 100 | B-1 | 20 | C-1/C-2 | 4288/1837 | D-1 | 5 |
| Example 11 | | | | | | | | | |
| Comparative | CR-12 | A-36 | 100 | B-1 | 20 | C-1/C-2 | 4288/1837 | D-1 | 5 |
| Example 12 | | | | | | | | | |
| Comparative | CR-13 | A-37 | 100 | B-1 | 20 | C-1/C-2 | 4288/1837 | D-1 | 5 |
| Example 13 | | | | | | | | | |
| Comparative | CR-14 | A-38 | 100 | B-1 | 20 | C-1/C-2 | 4288/1837 | D-1 | 5 |
| Example 14 | | | | | | | | | |
| Comparative | CR-15 | A-39 | 100 | — | — | C-1/C-2 | 4288/1837 | D-1 | 5 |
| Example 15 | | | | | | | | | |
| Comparative | CR-16 | A-25 | 100 | B-2 | 20 | C-1/C-2 | 4288/1837 | D-1 | 5 |
| Example 16 | | | | | | | | | |
| Comparative | CR-17 | A-25 | 100 | B-1 | 20 | C-1/C-2 | 4288/1837 | D-2 | 5 |
| Example 17 | | | | | | | | | |
| Comparative | CR-18 | A-25 | 100 | B-1 | 20 | C-1/C-2 | 4288/1837 | D-3 | 5 |
| Example 18 | | | | | | | | | |
| Comparative | CR-19 | A-40 | 100 | B-1 | 20 | C-1/C-2 | 4288/1837 | D-1 | 5 |
| Example 19 | | | | | | | | | |

### Formation of Positive-Tone Resist Pattern

The radiation-sensitive resin composition prepared as described above was applied on the surface of an 8-inch silicon wafer using a spin-coater (“CLEAN TRACK ACT8” available from Tokyo Electron Limited), and subjected to PB at 90° C. for 60 sec. Thereafter, cooling was carried out at 23° C. for 30 sec to form a resist film having an average thickness of 50 nm. Next, this resist film was irradiated with an electron beam using a simplified electron beam writer (“HL800D” available from Hitachi, Ltd.; output: 50 KeV, electric current density: 5.0 A/cm²). After the irradiation, the resist film was subjected to PEB at 90° C. for 60 sec. Then the resist film was developed by using a 2.38% by mass aqueous TMAH solution as an alkaline developer solution at 23° C. for 30 sec, followed by washing with water and thereafter drying to form a positive-tone resist pattern (line-and-space pattern with a line width of 150 nm).

### Formation of Negative-Tone Resist Pattern

A negative-tone resist pattern (line-and-space pattern with a line width of 150 nm) was formed by a procedure similar to that for the formation of the positive-tone resist pattern except that butyl acetate was used as the developer solution.

### Evaluations

On the positive-tone or negative-tone resist pattern formed as described above, LWR and CDU were measured in accordance with the following methods, and the measurements were designated as the LWR performance and CDU performance of each radiation-sensitive resin composition. The results of the evaluations are shown in Table 3. It is to be noted that in the following method, a scanning electron microscope (“S-9380” available from Hitachi High-Technologies Corporation) was used for a line-width measurement of the resist patterns.

LWR Performance

The resist pattern was observed from above the pattern using the scanning electron microscope. The line width of the pattern was measured at arbitrary 50 points in total, then a 3 Sigma value was determined from the distribution of the measurements, and the value was designated as “LWR performance (nm)”. The smaller value indicates a more favorable LWR performance. By comparing the measurement with a measurement in the case of using a radiation-sensitive resin composition that serves as an evaluation standard shown in Table 3, the LWR performance was evaluated to be: “favorable (A)” in the case of an improvement by no less than 10% being found (accounting for no greater than 90% of the measurement for the evaluation standard); “somewhat favorable (B)” in the case of an improvement by less than 10% being found (accounting for greater than 90% and less than 100% the measurement for the evaluation standard); or “unfavorable (C)” in the cases of an improvement not being found and deterioration being found (accounting for no less than 100% of the measurement for the evaluation standard).

CDU Performance

The resist pattern was observed from above the pattern using the scanning electron microscope. The line width of the pattern was measured at 20 points within the range of 400 nm, and an averaged value of the width was determined. The averaged value was determined at arbitrary 500 points in total, then a 3 Sigma value was determined from the distribution of the measurements, and 3 Sigma the value was designated as “CDU performance (nm)”. The smaller value indicates a more favorable CDU performance. By comparing the measurement with a measurement in the case of using a radiation-sensitive resin composition that serves as an evaluation standard shown in Table 3, the CDU performance was evaluated to be: “favorable (A)” in the case of an improvement by no less than 10% being found (accounting for no greater than 90% of the measurement for the evaluation standard); “somewhat favorable (B)” in the case of an improvement by less than 10% being found (accounting for greater than 90% and less than 100% the measurement for the evaluation standard); or “unfavorable (C)” in the cases of an improvement not being found and deterioration being found (accounting for no less than 100% of the measurement for the evaluation standard).

TABLE 3

| | | | Development | | Development with | |
|---|---|---|---|---|---|---|
| | Radiation- | | with alkali | | organic solvent | |
| | sensitive resin | Evaluation | LWR | CDU | LWR | CDU |
| | composition | standard | performance | performance | performance | performance |
| Example 1 | R-1 | CR-1 | A | A | A | A |
| Example 2 | R-2 | CR-1 | A | A | A | A |
| Example 3 | R-3 | CR-1 | A | A | A | A |
| Example 4 | R-4 | CR-1 | A | A | A | A |
| Example 5 | R-5 | CR-1 | A | A | A | A |
| Example 6 | R-6 | CR-1 | A | A | A | A |
| Example 7 | R-7 | CR-1 | A | A | A | A |
| Example 8 | R-8 | CR-1 | A | A | A | A |
| Example 9 | R-9 | CR-2 | A | A | A | A |
| Example 10 | R-10 | CR-3 | A | A | A | A |
| Example 11 | R-11 | CR-4 | A | A | A | A |
| Example 12 | R-12 | CR-5 | A | A | A | A |
| Example 13 | R-13 | CR-6 | A | A | A | A |
| Example 14 | R-14 | CR-7 | A | A | A | A |
| Example 15 | R-15 | CR-8 | A | A | A | A |
| Example 16 | R-16 | CR-9 | A | A | A | A |
| Example 17 | R-17 | CR-10 | A | A | A | A |
| Example 18 | R-18 | CR-11 | A | A | A | A |
| Example 19 | R-19 | CR-12 | A | A | A | A |
| Example 20 | R-20 | CR-13 | A | A | A | A |
| Example 21 | R-21 | CR-14 | A | A | A | A |
| Example 22 | R-22 | CR-15 | A | A | A | A |
| Example 23 | R-23 | CR-16 | A | A | A | A |
| Example 24 | R-24 | CR-17 | A | A | A | A |
| Example 25 | R-25 | CR-18 | A | A | A | A |
| Example 26 | R-26 | CR-1 | A | A | A | A |
| Example 27 | R-27 | CR-1 | B | B | B | B |

Comparative Example 19 failed to form a pattern under the evaluation conditions described above.

As is clear from the results shown in Table 3, all Examples resulted in favorable or somewhat favorable LWR performance and CDU performance. In other words, the radiation-sensitive resin compositions of Examples resulted in superior LWR performance and CDU performance to those of the radiation-sensitive resin compositions of Comparative Examples. It is to be noted that an exposure to electron beam is generally known to give a tendency similar to that in the case of the exposure to EUV. Therefore, it is considered that the radiation-sensitive resin compositions of the embodiments of the present invention will enable a resist pattern superior in LWR performance and CDU performance to be formed even in the case of an exposure to EUV.

According to the radiation-sensitive resin composition and the resist pattern-forming method of the embodiments of the present invention, formation of a resist pattern superior in LWR performance and CDU performance is enabled. Therefore, these can be suitably used in manufacture of semiconductor devices in which further progress of miniaturization is expected in the future.

Obviously, numerous modifications and variations of the present invention are possible in light of the above teachings. It is therefore to be understood that within the scope of the appended claims, the invention may be practiced otherwise than as specifically described herein.

1: A radiation-sensitive resin composition comprising:
a polymer;
a radiation-sensitive acid generator; and
a solvent,
wherein, the polymer comprises:
a first structural unit comprising: a first acid-labile group represented by formula (A); and an oxoacid group protected by the first acid-labile group, or a phenolic hydroxyl group protected by the first acid-labile group; and
a second structural unit comprising: a second acid-labile group other than the first acid-labile group; and an oxoacid group protected by the second acid-labile group, or a phenolic hydroxyl group protected by the second acid-labile group, 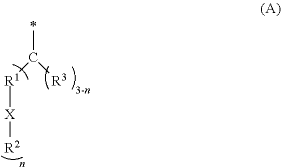
wherein, in the formula (A), R¹ represents a single bond or a divalent hydrocarbon group having 1 to 20 carbon atoms that is unsubstituted or substituted with a hydroxy group, an amino group, a cyano group, a nitro group or a fluorine atom; X represents a carbonyl group, a sulfonyl group, a sulfonyloxy group, —O—, or —S—; R² and R³ each independently represent a monovalent hydrocarbon group having 1 to 20 carbon atoms that is unsubstituted or substituted with a hydroxy group, an amino group, a cyano group, a nitro group or a fluorine atom; n is an integer of 1 to 3; and * denotes a bonding site to an oxy group in the oxoacid group protected or the phenolic hydroxyl group protected,
wherein
in a case in which R¹, R² and R³ are each present in a plurality of number, R¹s are identical or different, R²s are identical or different, and R³s are identical or different, or
at least two of: one or a plurality of R¹s; one or a plurality of R²s; and one or a plurality of R³s taken together represent an alicyclic structure having 3 to 20 ring atoms together with the carbon atom or carbon chain to which the at least two of the one or the plurality of R¹s, the one or the plurality of R²s and the one or the plurality of R³s bond, and R¹ other than the at least two of the one or the plurality of R¹s, the one or the plurality of R²s and the one or the plurality of R³s represents a single bond or a divalent hydrocarbon group having 1 to 20 carbon atoms that is unsubstituted or substituted with a hydroxy group, an amino group, a cyano group, a nitro group or a fluorine atom; and R² and R³ other than the at least two of the one or the plurality of R¹s, the one or the plurality of R²s and the one or the plurality of R³s each independently represent a monovalent hydrocarbon group having 1 to 20 carbon atoms that is unsubstituted or substituted with a hydroxy group, an amino group, a cyano group, a nitro group or a fluorine atom.

2: The radiation-sensitive resin composition according to claim 1, wherein X in the formula (A) represents a carbonyl group.

3: The radiation-sensitive resin composition according to claim 1, wherein R¹ in the formula (A) represents a single bond or an alkanediyl group having 1 to 10 carbon atoms that is unsubstituted or substituted with a hydroxy group, an amino group, a cyano group, a nitro group or a fluorine atom.

4: The radiation-sensitive resin composition according to claim 1, wherein the first structural unit is represented by formula (2-1) or (2-2). 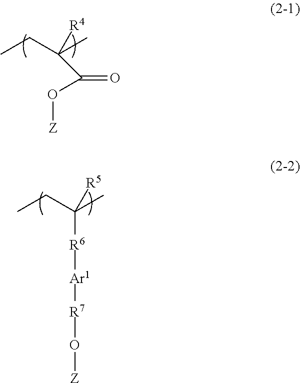
wherein,
in the formulae (2-1) and (2-2), Z represents the first acid-labile group represented by the formula (A),
in the formula (2-1), R⁴ represents a hydrogen atom, a fluorine atom, a methyl group or a trifluoromethyl group,
in the formula (2-2), R⁵ represents a hydrogen atom or a methyl group; R⁶ represents a single bond, —O—, —COO— or —CONH—; and Ar¹ represents a substituted or unsubstituted arenediyl group having 6 to 20 carbon atoms; and R⁷ represents a single bond or —CO—.

5: The radiation-sensitive resin composition according to claim 1, wherein the second structural unit is represented by formula (a-1) or (a-2): 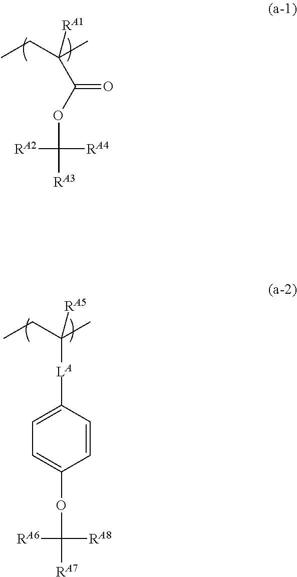
wherein,
in the formula (a-1), R^{A1} represents a hydrogen atom, a fluorine atom, a methyl group or a trifluoromethyl group; R^{A2} represents a monovalent hydrocarbon group having 1 to 20 carbon atoms; and R^{A3} and R^{A4} each independently represent a monovalent hydrocarbon group having 1 to 20 carbon atoms, or R^{A3} and R^{A4} taken together represent a ring structure having 3 to 20 ring atoms together with the carbon atom to which R^{A3} and R^{A4} bond,
in the formula (a-2), R^{A5} represents a hydrogen atom, a fluorine atom, a methyl group or a trifluoromethyl group; R^{A6} represents a hydrogen atom, a monovalent hydrocarbon group having 1 to 20 carbon atoms, or a monovalent oxyhydrocarbon group having 1 to 20 carbon atoms; R^{A7} and R^{A8} each independently represent a monovalent hydrocarbon group having 1 to 20 carbon atoms or a monovalent oxyhydrocarbon group having 1 to 20 carbon atoms; and L^{A} represents a single bond, —O—, —COO— or —CONH—.

6: A resist pattern-forming method comprising:
applying the radiation-sensitive resin composition according to claim 1 directly or indirectly on an upper face side of a substrate to form a resist film;
exposing the resist film; and
developing the resist film exposed.

7: The resist pattern-forming method according to claim 6, wherein the resist film is developed with a developer solution comprising an organic solvent as a principal component.

8: A radiation-sensitive resin composition comprising:
a polymer;
a radiation-sensitive acid generator; and
a solvent,
wherein, the polymer comprises:
a first structural unit comprising: a first acid-labile group represented by formula (1); and an oxoacid group protected by the first acid-labile group, or a phenolic hydroxyl group protected by the first acid-labile group; and
a second structural unit comprising: a second acid-labile group other than the first acid-labile group; and an oxoacid group protected by the second acid-labile group, or a phenolic hydroxyl group protected by the second acid-labile group, 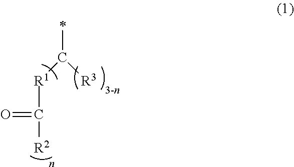
wherein, in the formula (1),
n is 1;
R¹ represents a single bond or a divalent hydrocarbon group having 1 to 20 carbon atoms that is unsubstituted or substituted with a hydroxy group, an amino group, a cyano group, a nitro group or a fluorine atom, and R² represents a monovalent hydrocarbon group having 1 to 20 carbon atoms that is unsubstituted or substituted with a hydroxy group, an amino group, a cyano group, a nitro group or a fluorine atom, or R¹ and R² taken together represent an alicyclic structure having 3 to 20 ring atoms together with the carbon atom to which R¹ and R² bond;
two R³s, together with the carbon atom to which the two R³s bond, taken together represent an alicyclic structure having 3 to 20 ring atoms; and
* denotes a bonding site to an oxy group in the oxoacid group protected or the phenolic hydroxyl group protected.

9: The radiation-sensitive resin composition according to claim 8, wherein R¹ in the formula (1) represents a single bond or an alkanediyl group having 1 to 10 carbon atoms that is unsubstituted or substituted with a hydroxy group, an amino group, a cyano group, a nitro group or a fluorine atom.

10: The radiation-sensitive resin composition according to claim 8, wherein the first structural unit is represented by formula (2-1) or (2-2). 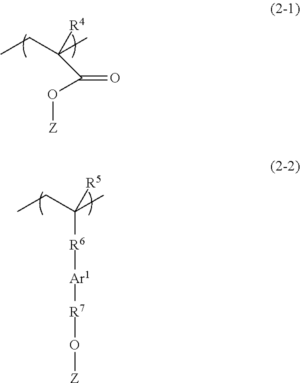
wherein,
in the formulae (2-1) and (2-2), Z represents the first acid-labile group represented by the formula (1),
in the formula (2-1), R⁴ represents a hydrogen atom, a fluorine atom, a methyl group or a trifluoromethyl group,
in the formula (2-2), R⁵ represents a hydrogen atom or a methyl group; R⁶ represents a single bond, —O—, —COO— or —CONH—; and Ar¹ represents a substituted or unsubstituted arenediyl group having 6 to 20 carbon atoms; and R⁷ represents a single bond or —CO—.

11: The radiation-sensitive resin composition according to claim 8, wherein the second structural unit is represented by formula (a-1) or (a-2): 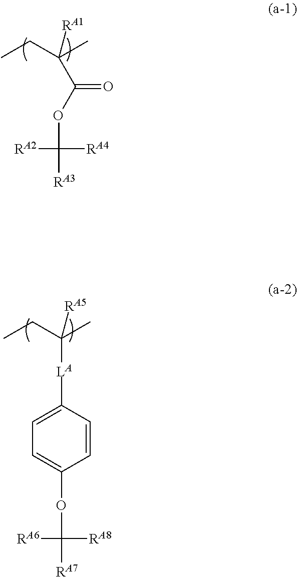
wherein,
in the formula (a-1), R^{A1} represents a hydrogen atom, a fluorine atom, a methyl group or a trifluoromethyl group; R^{A2} represents a monovalent hydrocarbon group having 1 to 20 carbon atoms; and R^{A3} and R^{A4} each independently represent a monovalent hydrocarbon group having 1 to 20 carbon atoms, or R^{A3} and R^{A4} taken together represent a ring structure having 3 to 20 ring atoms together with the carbon atom to which R^{A3} and R^{A4} bond,
in the formula (a-2), R^{A5} represents a hydrogen atom, a fluorine atom, a methyl group or a trifluoromethyl group; R^{A6} represents a hydrogen atom, a monovalent hydrocarbon group having 1 to 20 carbon atoms, or a monovalent oxyhydrocarbon group having 1 to 20 carbon atoms; R^{A7} and R^{A8} each independently represent a monovalent hydrocarbon group having 1 to 20 carbon atoms or a monovalent oxyhydrocarbon group having 1 to 20 carbon atoms; and L^{A} represents a single bond, —O—, —COO— or —CONH—.

12: A resist pattern-forming method comprising:
applying the radiation-sensitive resin composition according to claim 8 directly or indirectly on an upper face side of a substrate to form a resist film;
exposing the resist film; and
developing the resist film exposed.

13: The resist pattern-forming method according to claim 12, wherein the resist film is developed with a developer solution comprising an organic solvent as a principal component.
